(19) United States
(12) Patent Application Publication
(10) Pub. No.: US 2021/0385965 A1
(43) Pub. Date: Dec. 9, 2021

(54) HEAT STORAGE MEMBER, ELECTRONIC DEVICE, MANUFACTURING METHOD OF HEAT STORAGE MEMBER, AND COMPOSITION FOR FORMING PROTECTIVE LAYER

(71) Applicant: FUJIFILM Corporation, Tokyo (JP)

(72) Inventors: Tetsuro MITSUI, Shizuoka (JP); Naotoshi SATO, Shizuoka (JP); Miyoko HARA, Shizuoka (JP); Masahiro HATTA, Shizuoka (JP); Hiroshi KAWAKAMI, Shizuoka (JP); Hirokazu KITO, Shizuoka (JP); Aya NAKAYAMA, Shizuoka (JP); Takuto MATSUSHITA, Shizuoka (JP); Kyohei OGAWA, Shizuoka (JP)

(73) Assignee: FUJIFILM Corporation, Tokyo (JP)

(21) Appl. No.: 17/407,166

(22) Filed: Aug. 19, 2021

Related U.S. Application Data
(63) Continuation of application No. PCT/JP2020/001672, filed on Jan. 20, 2020.

(30) Foreign Application Priority Data
Feb. 28, 2019 (JP) 2019-036983
Mar. 25, 2019 (JP) 2019-057347
Jun. 28, 2019 (JP) 2019-122065
Aug. 30, 2019 (JP) 2019-158766
Sep. 2, 2019 (JP) 2019-159485
Oct. 7, 2019 (JP) 2019-184716
Dec. 26, 2019 (JP) 2019-236307

(51) Int. Cl. H05K 7/20; F28D 20/02; F28D 21/00

(52) U.S. Cl. CPC H05K 7/2039; F28D 2021/0028; F28D 21/00; F28D 20/023

(57) ABSTRACT

An object of the present invention is to provide a heat storage member having excellent flame retardance. Another object of the present invention is to provide an electronic device including a heat storage member, a manufacturing method of a heat storage member, and a composition for forming a protective layer.

The heat storage member according to an embodiment of the present invention includes a protective layer and a heat storage layer including a heat storage material, in which the protective layer has a crosslinking structure.

### CROSS-REFERENCE TO RELATED APPLICATIONS

This application is a Continuation of PCT International Application No. PCT/JP2020/001672 filed on Jan. 20, 2020, which claims priority under 35 U.S.C. § 119(a) to Japanese Patent Application No. 2019-036983 filed on Feb. 28, 2019, Japanese Patent Application No. 2019-057347 filed on Mar. 25, 2019, Japanese Patent Application No. 2019-159485 filed on Sep. 2, 2019, Japanese Patent Application No. 2019-122065 filed on Jun. 28, 2019, Japanese Patent Application No. 2019-158766 filed on Aug. 30, 2019, Japanese Patent Application No. 2019-184716 filed on Oct. 7, 2019, and Japanese Patent Application No. 2019-236307 filed on Dec. 26, 2019. Each of the above applications is hereby expressly incorporated by reference, in its entirety, into the present application.

### BACKGROUND OF THE INVENTION

### 1. Field of the Invention

The present disclosure relates to a heat storage member, an electronic device, a manufacturing method of a heat storage member, and a composition for forming a protective layer.

### 2. Description of the Related Art

In equipment such as an electronic device, a building, an automobile, and an exhaust heat utilization system, a heat storage member that stores heat from a heat generating body and suppresses the overall temperature rise is used. The heat storage member includes a heat storage material that functions as a material that can store heat generated outside a heat storage layer.

For example, WO2018/066130A discloses a heat control sheet comprising a heat storage material including a copolymer of ethylene and an olefin having 3 or more carbon atoms and a chain saturated hydrocarbon compound, and a heat storage layer which includes a metal layer and the heat storage material formed on the metal layer.

### SUMMARY OF THE INVENTION

The present inventors have studied an existing heat storage member based on the description of WO2018/066130A, and have found that in many cases, a combustible material such as a paraffin is used as the heat storage material included in the heat storage member, but in a case in which a flame retardant or the like is mixed with the heat storage material, a volume and a mass of components other than the heat storage material in the heat storage member are increased, and thus an amount of heat storage per unit volume or unit mass may be decreased.

The present disclosure has been made in view of the above circumstances. An object to be solved by the present disclosure is to provide a heat storage member having excellent flame retardance.

Another object to be solved by the present disclosure is to provide an electronic device including a heat storage member, a manufacturing method of a heat storage member, and a composition for forming a protective layer.

Specific means for solving the objects include the aspects as follows.

[1] A heat storage member comprising a protective layer, and a heat storage layer which includes a heat storage material, in which the protective layer has a crosslinking structure.

[2] The heat storage member according to [1], in which the protective layer includes at least one selected from the group consisting of a resin containing a fluorine atom and a siloxane condensate.

[3] The heat storage member according to [1] or [2], in which the protective layer includes a flame retardant containing a phosphorus atom.

[4] The heat storage member according to any one of [1] to [3], in which the protective layer includes a curing agent.

[5] The heat storage member according to any one of [1] to [4], in which no fissuring is present on a surface of the protective layer opposite to a surface thereof facing the heat storage layer.

[6] The heat storage member according to any one of [1] to [5], in which the protective layer has a thickness of 10 μm or less.

[7] The heat storage member according to any one of [1] to [6], in which a ratio of a thickness of the protective layer to a thickness of the heat storage layer is 1/20 or less.

[8] The heat storage member according to any one of [1] to [7], in which an elongation ratio at the time of tensile breaking is 20% or more.

[9] The heat storage member according to any one of [1] to [8], in which the heat storage layer and the protective layer are in contact with each other.

[10] The heat storage member according to any one of [1] to [9], in which a content ratio of the heat storage material to a total mass of the heat storage layer is 65% by mass or more.

[11] The heat storage member according to any one of [1] to [10], in which the heat storage layer includes a microcapsule which encompasses at least a part of the heat storage material.

[12] The heat storage member according to any one of [1] to [11], in which the heat storage material includes a latent heat storage material.

[13] The heat storage member according to any one of [1] to [12], in which a content of the heat storage material having a largest content included in the heat storage layer to contents of all of the heat storage materials included in the heat storage layer is 98% by mass or more.

[14] An electronic device comprising the heat storage member according to any one of [1] to [13].

[15] The electronic device according to [14], further comprising a heat generating body.

[16] A manufacturing method of a heat storage member which includes a heat storage layer including a heat storage material and a protective layer having a crosslinking structure, the method comprising disposing the protective layer to be in contact with at least one surface of the heat storage layer.

[17] A composition for forming a protective layer comprising at least one selected from the group consisting of a resin containing a fluorine atom and a siloxane resin or a precursor thereof, and a flame retardant containing a phosphorus atom.

According to an embodiment of the present disclosure, it is possible to provide a heat storage member having excellent heat storage property and an electronic device including the heat storage member. Further, according to the embodiment of the present disclosure, it is possible to provide a manufacturing method of a heat storage member and a composition for forming a protective layer.

### DESCRIPTION OF THE PREFERRED EMBODIMENTS

Hereinafter, a heat storage member according to the present disclosure will be described in detail.

Note that the description of the configuration elements according to the embodiments of the present disclosure is based on the typical embodiment according to the present disclosure, but the present disclosure is not limited to such embodiments.

In the present specification, the numerical range represented by “to” denotes a range including numerical values described before and after “to” as a minimum value and a maximum value, respectively. In the numerical range described stepwise in the present disclosure, an upper limit value or a lower limit value described in a certain numerical range may be replaced with an upper limit value or a lower limit value of another numerical range described stepwise. Further, in the numerical range described in the present disclosure, the upper limit value or the lower limit value described in a certain numerical range may be replaced with a value shown in Examples.

In the numerical range described stepwise in the present specification, an upper limit value or a lower limit value described in one numerical range may be replaced with an upper limit value or a lower limit value of another numerical range described stepwise. Further, in the numerical range described in the present specification, the upper limit value or the lower limit value in the numerical range may be replaced with a value shown in Examples.

Furthermore, in the present disclosure, “% by mass” and “% by weight” are synonymous, and “parts by mass” and “parts by weight” are synonymous.

Furthermore, in the present disclosure, a combination of two or more preferred embodiments is a more preferred embodiment.

In the present disclosure, an amount of each component in a composition or a layer is a total amount of a plurality of substances present in the composition unless otherwise noted, in a case in which the plurality of substances corresponding to each component are present in the composition.

[Heat Storage Member]

The heat storage member according to the present disclosure includes a protective layer and a heat storage layer including a heat storage material, in which the protective layer has a crosslinking structure.

It is preferable that the protective layer be disposed on the outermost layer of the heat storage member. Here, “the protective layer is disposed on the outermost layer” of the heat storage member means that the protective layer is disposed on any of both ends of a stacked body which configures the heat storage member in a stacking direction. Further, another layer may be provided on a surface of the protective layer opposite to a surface thereof facing the heat storage layer.

The configuration of the heat storage member will be described below for each layer.

[Heat Storage Layer]

The heat storage layer included in the heat storage member according to the present disclosure is not particularly limited as long as the layer includes the heat storage material. The heat storage material included in the heat storage layer may be present in a form encompassed in a microcapsule or may be present in a form not encompassed in the microcapsule.

In the heat storage layer, it is preferable that at least a part of the heat storage material be present to be encompassed in the microcapsule from the viewpoint that the heat storage material can be stably present in a phase state depending on the temperature and the viewpoints that the heat storage material which becomes liquid at high temperature can be prevented from leaking out of the heat storage layer, the surrounding members of the heat storage layer can be prevented from being contaminated, and the heat storage ability of the heat storage layer can be maintained.

Hereinafter, the heat storage layer will be specifically described with the heat storage layer including the microcapsule which encompasses the heat storage material as an example.

<Microcapsule>

The microcapsule included in the heat storage layer has a core portion and a wall portion for encompassing a core material (encompassed material (also referred to as an encompassed component)) which forms the core portion, and the wall portion is also referred to as a “capsule wall”.

(Core Material)

The microcapsule encompasses the heat storage material as the core material (encompassed component).

Since at least a part of the heat storage material is present by being encompassed in the microcapsule, the heat storage material can be stably present in a phase state depending on the temperature.

Heat Storage Material

The heat storage material can be appropriately selected from materials which can repeat the phase change between the solid phase and the liquid phase due to the state change of melting and solidification depending on the temperature change, depending on a target (for example, the heat generating body) or a purpose of heat amount control or heat utilization, or the like.

It is preferable that the phase change of the heat storage material be based on the melting point of the heat storage material itself.

The heat storage material may be, for example, any of a material which can store heat which is generated outside the heat storage layer as sensible heat or a material (hereinafter, also referred to as a “latent heat storage material”) which can store heat which is generated outside the heat storage layer as latent heat. It is preferable that the heat storage material be a material which can release the stored heat.

Above all, it is more preferable that the heat storage material be the latent heat storage material from the viewpoint of the control of the amount of heat which can be transferred, the control speed of heat, and the magnitude of the amount of heat.

Latent Heat Storage Material

The latent heat storage material means a material which stores heat, which is generated outside the heat storage layer, as latent heat, and transfers heat due to latent heat by repeating the change between melting and solidification with the melting point determined by the material as a phase change temperature.

The latent heat storage material can utilize the heat of fusion at the melting point and the heat of solidification at a solidifying point, store heat depending on the phase change between the solid and the liquid, and release heat.

The latent heat storage material can be selected from compounds having a melting point and capable of changing a phase.

Examples of the latent heat storage material include ice (water); an aliphatic hydrocarbon such as paraffin (for example, isoparaffin and normal paraffin) and the like; an inorganic salt; an organic acid ester compound such as caprylic/capric triglyceride, methyl myristate (melting point of 16° C. to 19° C.), isopropyl myristate (melting point of 167° C.), and dibutyl phthalate (melting point of −35° C.); an aromatic hydrocarbon such as an alkylnaphthalene compound such as diisopropylnaphthalene (melting point of 67° C. to 70° C.), a diarylalkane compound such as 1-phenyl-1-xylylethane (melting point lower than −50° C.), an alkylbiphenyl compound such as 4-isopropylbiphenyl (melting point of 11° C.), a triarylmethane compound, an alkylbenzene compound, a benzylnaphthalene compound, a diarylalkylene compound, and an aryl indane compound; natural animal and plant oils such as camellia oil, soybean oil, corn oil, cotton seed oil, rapeseed oil, olive oil, coconut oil, castor oil, and fish oil; and high boiling point distillates of natural products such as mineral oil.

Among the latent heat storage materials, from the viewpoint of exhibiting the excellent heat storage property, paraffin is preferable.

As the paraffin, an aliphatic hydrocarbon having a melting point of 0° C. or higher is preferable, and an aliphatic hydrocarbon having a melting point of 0° C. or higher and having 14 or more carbon atoms is more preferable.

Examples of the aliphatic hydrocarbon having the melting point of 0° C. or higher include tetradecane (melting point of 6° C.), pentadecane (melting point of 10° C.), hexadecane (melting point of 18° C.), heptadecane (melting point of 22° C.), octadecane (melting point of 28° C.), nonadecane (melting point of 32° C.), icosane (melting point of 37° C.), henicosane (melting point of 40° C.), docosane (melting point of 44° C.), tricosane (melting point of 48° C. to 50° C.), tetracosane (melting point of 52° C.), pentacosane (melting point of 53° C. to 56° C.), heptacosane (melting point of 60° C.), octacosane (melting point of 65° C.), nonacosane (melting point of 63° C. to 66° C.), and triacontane (melting point of 64° C. to 67° C.).

As the inorganic salt, an inorganic hydrated salt is preferable, and the examples thereof include alkali metal chloride hydrate (for example, sodium chloride dihydrate), alkali metal acetate hydrate (for example, sodium acetate hydrate), alkali metal sulfate hydrate (for example, sodium sulfate hydrate), alkali metal thiosulfate hydrate (for example, sodium thiosulfate hydrate), alkaline earth metal sulfate hydrate (for example, calcium sulfate hydrate), and alkaline earth metal chloride hydrate (for example, calcium chloride hydrate).

The melting point of the heat storage material can be selected depending on the type of the heat generating body which generates heat, a heat generating temperature of the heat generating body, a temperature or a holding temperature after cooling, and the purpose of a cooling method. By appropriately selecting the melting point, for example, it is possible to stably maintain the temperature of the heat generating body which generates heat at an appropriate temperature which does not overcool.

It is preferable that the heat storage material be selected mainly from a material having the melting point at a center temperature of a target temperature range (for example, an operating temperature of the heat generating body; hereinafter, also referred to as a “heat control range”).

The heat storage material can be selected depending on the melting point of the heat storage material for the heat control range. The heat control range is set depending on the applications (for example, the type of heat generating body).

Specifically, the melting point of the heat storage material to be selected differs depending on the heat control range, but the material having the following melting points can be suitably selected as the heat storage material. The heat storage material is suitable in a case in which the application is an electronic device (in particular, a small, portable, or handy electronic device).

(1) Among the heat storage materials described above (preferably, the latent heat storage material), the heat storage material having the melting point of 0° C. or higher and 80° C. or lower is preferable.

In a case in which the heat storage material having the melting point of 0° C. or higher and 80° C. or lower is used, the material having the melting point lower than 0° C. or higher than 80° C. is not included in the heat storage material. Among the materials having the melting point lower than 0° C. or higher than 80° C., the material in the liquid state may be used in combination with the heat storage material as a solvent.

(2) Among the above, the heat storage material having the melting point of 10° C. or higher and 70° C. or lower is more preferable.

In a case in which the heat storage material having the melting point of 10° C. or higher and 70° C. or lower is used, the material having the melting point lower than 10° C. or higher than 70° C. is not included in the heat storage material. Among the materials having the melting point lower than 10° C. or higher than 70° C., the material in the liquid state may be used in combination with the heat storage material as a solvent.

(3) Further, the heat storage material having the melting point of 15° C. or higher and 50° C. or lower is further preferable.

In a case in which the heat storage material having the melting point of 15° C. or higher and 50° C. or lower is used, the material having the melting point lower than 15° C. or higher than 50° C. is not included in the heat storage material. Among the materials having the melting point lower than 15° C. or higher than 50° C., the material in the liquid state may be used in combination with the heat storage material as a solvent.

The heat storage material may be used alone or in combination of a plurality of types. By using the heat storage material alone or a plurality of types of heat storage materials having different melting points, it is possible to adjust the temperature range in which the heat storage property is exhibited and the amount of heat storage depending on the applications.

The temperature range in which heat can be stored can be expanded by mixing two types of other heat storage materials having the melting points higher and lower the center temperature with the heat storage material, as a center material, having the melting point at the center temperature at which the heat storage effect of the heat storage material is desired. An example of a case in which the paraffin is used as the heat storage material will be specifically described. Paraffin a having the melting point at the center temperature at which the heat storage effect of the heat storage material is desired is used as a center material, and the paraffin a and two types of other paraffins having the carbon atoms more than or less than the carbon atoms of the paraffin a are mixed, so that the material can be designed to have a wide temperature range (heat control range).

Further, the content ratio of paraffin having the melting point at the center temperature at which the heat storage effect is desired to the total mass of the heat storage material is preferably 80% by mass or more, more preferably 90% by mass or more, and further preferably 95% by mass or more.

On the other hand, depending on the applications such as the electronic device, it is also preferable that the heat storage material included in the heat storage layer be substantially one type. In a case in which the heat storage material to be used is substantially one type, the heat storage layer is filled with the heat storage material with the high purity, so that the endothermic property of the electronic device with respect to the heat generating body is good. Here, substantially one type of the heat storage material means that the content of the heat storage material having the largest content among a plurality of the heat storage materials included in the heat storage layer to the total mass of all of the heat storage materials included in the heat storage layer is 95% by mass or more, and is preferably 98% by mass or more. The upper limit value is not particularly limited and need only be 100% by mass or less.

In a case in which the paraffin is used as the latent heat storage material, for example, the paraffin may be used alone or in combination of two types or more. In a case in which a plurality of paraffins having different melting points are used, it is possible to widen the temperature range in which the heat storage property is exhibited.

In a case in which the plurality of paraffins are used, from the viewpoint of the temperature range in which the heat storage property is exhibited and the amount of heat storage, the content ratio of the main paraffin to the total mass of the paraffin is preferably 80% to 100% by mass, more preferably 90% to 100% by mass, and further preferably 95% to 100% by mass. The “main paraffin” refers to the paraffin having the largest content among the plurality of paraffins which are contained. The content of the main paraffin to the total amount of the plurality of paraffins is preferably 50% by mass or more.

The content ratio of the paraffin to the total mass of the heat storage material (preferably, latent heat storage material) is preferably 80% to 100% by mass, more preferably 90% to 100% by mass, and further preferably 95% to 100% by mass.

In the heat storage layer, the heat storage material may be present outside the microcapsule. That is, the heat storage layer may include the heat storage material which is encompassed in the microcapsule, and the heat storage material which is present inside the heat storage layer and outside the microcapsule. In this case, it is preferable that 95% by mass or more of the heat storage material be encompassed in the microcapsule based on the total mass of the heat storage material included in the heat storage layer. That is, the content ratio (encompassing ratio) of the heat storage material which is encompassed in the microcapsule is preferably 95% by mass or more based on the total mass of the heat storage material included in the heat storage layer. The upper limit is not particularly limited, but 100% by mass can be adopted, for example.

As the heat storage material in the heat storage layer, 95% by mass or more of the heat storage material based on the total mass is encompassed in the microcapsule, so that it is advantageous from the viewpoints that the heat storage material which becomes a liquid at a high temperature can be prevented from leaking out of the heat storage layer, the surrounding members and the like in which the heat storage layer is used can be prevented from being contaminated, and the heat storage ability as the heat storage layer can be maintained.

From the viewpoint of the heat storage property of the heat storage layer, the content ratio of the heat storage material in the heat storage layer to the total mass of the heat storage layer is preferably 65% by mass or more, more preferably 75% by mass or more, and further more preferably 80% by mass or more. The content ratio of the heat storage material in the heat storage layer to the total mass of the heat storage layer is preferably 99.9% by mass or less, more preferably 99% by mass or less, and further preferably 98% by mass or less.

The measurement of the content ratio of the heat storage material in the heat storage layer is performed by the method as follows.

First, the heat storage material is extracted from the heat storage layer, and the type of the heat storage material is identified. In a case in which the heat storage material is configured by a plurality of types, the mixing ratio thereof is also identified. Examples of the identification method include known methods such as nuclear magnetic resonance (NMR) measurement and infrared spectroscopy (IR) measurement. Further, as an example of the extracting method of the heat storage material from the heat storage layer, there is a method of immersing the heat storage layer in the solvent (for example, an organic solvent) to extract the heat storage material.

Next, the heat storage material included in the heat storage layer identified by the above procedure is separately prepared, and a heat absorption amount (J/g) of the heat storage material alone is measured by using differential scanning calorimeter (DSC). The obtained heat absorption amount is defined as a heat absorption amount A. As described above, in a case in which the heat storage material is configured by a plurality of types, the heat storage material with the mixing ratio is separately prepared and the heat absorption amount is measured.

Then, the heat absorption amount of the heat storage layer is measured by the same method as above. The obtained heat absorption amount is defined as a heat absorption amount B.

Next, a ratio X (%) {(B/A)×100} of the heat absorption amount B to the heat absorption amount A is calculated. The ratio X corresponds to the content ratio of the heat storage material in the heat storage layer (the ratio of the content of the heat storage material to the total mass of the heat storage layer). For example, in a case in which the heat storage layer is configured by only the heat storage material, the heat absorption amount A and the heat absorption amount B have the same value, and the ratio X (%) is 100%. On the other hand, in a case in which the content ratio of the heat storage material in the heat storage layer is a predetermined ratio, the heat absorption amount is a value corresponding to the ratio. That is, the content ratio of the heat storage material in the heat storage layer can be obtained by comparing the heat absorption amount A and the heat absorption amount B.

Other Components

Examples of other components that can be encompassed in the microcapsule as the core material include the solvent and an additive such as the flame retardant.

Other components can be encompassed in the microcapsule as the core material, but from the viewpoint of the heat storage property, the content ratio of the heat storage material in the core material to the total mass of the core material is preferably 80% to 100% by mass, and more preferably 100% by mass.

In the core portion, the microcapsule may include the solvent as an oil component as long as the effects of the heat storage property in the present disclosure are not significantly impaired.

Examples of the solvent include the heat storage material described above of which melting point is outside the temperature range in which the heat storage layer is used (heat control range; for example, the operating temperature of the heat generating body). That is, the solvent refers to a solvent which does not change the phase in the liquid state in the heat control range, and is distinguished from the heat storage material which undergoes a phase transition in the heat control range to cause an endothermic reaction or a heat dissipation reaction.

The content ratio of the solvent in the encompassed component to the total mass of the encompassed component is preferably less than 30% by mass, more preferably less than 10% by mass, and further preferably 1% by mass or less. The lower limit is not particularly limited, but 0% by mass can be adopted, for example.

The solvent may be used alone or in combination of two types or more.

In addition to the above components, the core material in the microcapsule can encompass, as needed, additives such as an ultraviolet absorbing agent, a light stabilizer, an antioxidant, a wax, and an odor suppressant.

(Content Ratio of Microcapsule)

In many cases, the content ratio of the microcapsule in the heat storage layer to the total mass of the heat storage layer is 70% by mass or more. Above all, it is preferably 75% by mass or more. By setting the content ratio of the microcapsule to 75% by mass or more, the presence amount of the heat storage materials to the total mass of the heat storage layer can be increased, and as a result, the heat storage layer which exhibits the excellent heat storage property is obtained.

It is preferable that the content ratio of the microcapsule in the heat storage layer be high, from the viewpoint of the heat storage property. Specifically, the content ratio of the microcapsule in the heat storage layer is preferably 80% by mass or more, more preferably 85% to 99% by mass, and further preferably 90% to 99% by mass.

The microcapsule may be used alone or in combination of two types or more.

(Wall Portion (Capsule Wall))

The microcapsule includes the wall portion (capsule wall) which encompasses the core material.

The microcapsule has the capsule wall, so that capsule particles can be formed and the core material described above which forms the core portion can be encompassed.

Forming Material of Capsule Wall

The material which forms the capsule wall in the microcapsule is not particularly limited as long as the material is a polymer, and examples thereof include polyurethane, polyurea, polyurethane urea, a melamine resin, and an acrylic resin. From the viewpoint of thinning the capsule wall to impart the excellent heat storage property, polyurethane, the material is preferably polyurea, polyurethane urea, or a melamine resin, and more preferably polyurethane, polyurea, or polyurethane urea. Further, polyurethane, polyurea, or polyurethane urea is more preferable from the viewpoint of being capable of preventing a case in which a phase change, a structural change, or the like of the heat storage material is unlikely to occur at the interface between the wall material and the heat storage material.

Further, it is preferable that the microcapsule be present as a deformable particle.

In a case in which the microcapsule is the deformable particle, the microcapsule can be deformed without breaking, and a filling ratio of the microcapsule can be improved. As a result, it is possible to increase the amount of the heat storage material in the heat storage layer, and more excellent heat storage property can be realized. From this viewpoint, polyurethane, polyurea, or polyurethane urea is preferable as the material which forms the capsule wall.

Deformation of microcapsule without breaking can be regarded as a deformed state as long as, regardless of the degree of deformation, deformation is recognized from the shape of each microcapsule in a state in which no external pressure is applied. For example, it refers to a property of relaxing the pressure applied to the capsule by deformation and maintaining a state in which the core material is encompassed in the microcapsule without capsule wall breaking even in a case in which the microcapsules are pressed against each other in the heat storage layer and the pressure applied to each capsule, in a case in which microcapsules are to be densely present in the heat storage layer.

The deformation which occurs in the microcapsule includes deformation in which spherical surfaces come into contact with each other to form a flat contact surface, for example, in a case in which the microcapsules are pressed against each other in the heat storage layer.

From the viewpoint, the deformation ratio of the microcapsule is preferably 10% or more, and more preferably 30% or more. Also, from the viewpoints of the physical strength and the durability of the capsule, the upper limit of the deformation ratio of the microcapsule may be 80% or less.

(Manufacturing Method of Microcapsule)

The microcapsule can be manufactured, for example, by the following method.

In a case in which the capsule wall is formed of polyurethane, polyurea, or polyurethane urea, examples of the manufacturing method of the microcapsule include a method in which an interfacial polymerization method is applied, which includes a step (emulsification step) of dispersing the oil phase including the heat storage material and a capsule wall material in the water phase including the emulsifier to prepare an emulsified liquid, and a step (capsulizing step) of polymerizing the capsule wall material at the interface between the oil phase and the water phase to form the capsule wall, and forming the microcapsule which encompasses the heat storage material.

Examples of the capsule wall material include the capsule wall material including polyisocyanate and at least one selected from the group consisting of polyol and polyamine. A part of polyisocyanate may react with water in a reaction system to be polyamine. Therefore, in a case in which the capsule wall material includes at least polyisocyanate, a part of the polyisocyanate can be converted into polyamine to react with polyamine to synthesize polyurea.

In a case in which the capsule wall is formed of a melamine formaldehyde resin, a coacervation method including a step (emulsification step) of dispersing the oil phase including the heat storage material in the water phase including the emulsifier to prepare the emulsified liquid, and a step (capsulizing step) of adding the capsule wall material to the water phase, forming a polymer layer of the capsule wall material on a surface of emulsified liquid droplet, and forming the microcapsule which encompasses the heat storage material can be applied to manufacture the microcapsule.

Emulsification Step

In the emulsification step, in a case in which the capsule wall is formed of polyurethane, polyurea, or polyurethane urea, the oil phase including the heat storage material and the capsule wall material is dispersed in the water phase including the emulsifier to prepare the emulsified liquid.

Further, in a case in which the capsule wall is formed of a melamine formaldehyde resin, the oil phase including the heat storage material is dispersed in the water phase including the emulsifier to prepare the emulsified liquid.

˜Emulsified Liquid˜

The emulsified liquid is formed by dispersing the oil phase including the heat storage material and, as needed, the capsule wall material in the water phase including the emulsifier.

(1) Oil Phase

The oil phase includes at least the heat storage material, and may further include components such as the capsule wall material, the solvent, and/or the additive, as needed.

Examples of the solvent include the heat storage material described above of which melting point is outside the temperature range in which the heat storage layer is used (heat control range; for example, the operating temperature of the heat generating body).

(2) Water Phase

The water phase includes at least an aqueous medium and the emulsifier.

Aqueous Medium

Examples of the aqueous medium include water and a mixed solvent of water and a water-soluble organic solvent, and water is preferable. The “water-soluble” of the water-soluble organic solvent means that a dissolved amount of a target substance in 100% by mass of water at 25° C. is 5% by mass or more.

The content of the aqueous medium is preferably 20% to 80% by mass, more preferably 30% to 70% by mass, and further preferably 40% to 60% by mass, based on the total mass of the emulsified liquid which is a mixture of the oil phase and the water phase.

Emulsifier

A dispersing agent, a surfactant, or a combination thereof is included in the emulsifier.

Examples of the dispersing agent include a binder which will be described below, and polyvinyl alcohol is preferable.

As the polyvinyl alcohol, a commercially available product may be used, and examples thereof include Kuraray Poval series manufactured by Kuraray Co., Ltd. (for example, Kuraray Poval PVA-217E, Kuraray Poval KL-318, and the like).

From the viewpoint of the dispersibility of the microcapsule, the degree of polymerization of the polyvinyl alcohol is preferably 500 to 5000, and more preferably 1000 to 3000.

Examples of the surfactant include a nonionic surfactant, an anionic surfactant, a cationic surfactant, and an amphoteric surfactant. The surfactant may be used alone or may be used in a combination of two types or more.

As the emulsifier, the emulsifier which is able to be bonded to polyisocyanate described above is preferable from the viewpoint of improving a film hardness. For example, in the case in which microcapsule is manufactured by using the capsule wall material including polyisocyanate, polyvinyl alcohol as the emulsifier is able to be bonded to polyisocyanate. That is, the hydroxyl group in polyvinyl alcohol is able to be bonded to polyisocyanate.

The concentration of the emulsifier is preferably more than 0% by mass and 20% by mass or less, more preferably 0.005% to 10% by mass, further preferably 0.01% to 10% by mass, and particularly preferably 1% to 5% by mass, based on the total mass of the emulsified liquid which is a mixture of the oil phase and the water phase.

As will be described below, in a case in which the heat storage layer is manufactured by using the dispersion liquid in which the microcapsules produced by using the emulsifier are dispersed, the emulsifier may remain as the binder in the heat storage layer. As will be described below, in order to reduce the content ratio of the binder in the heat storage layer, it is preferable that the usage amount of the emulsifier be small as long as the emulsification performance is not impaired.

The water phase may include other components such as an ultraviolet absorbing agent, an antioxidant, and a preservative, as needed.

˜Dispersion˜

Dispersion refers to dispersing the oil phase as oil droplets in the water phase (emulsification). Dispersion can be performed by using a known unit used to disperse the oil phase and the water phase, such as homogenizer, manton gaulin, ultrasound disperser, dissolver, keddy mill, or other known dispersion apparatuses.

The mixing ratio of the oil phase to the water phase (oil phase mass/water phase mass) is preferably 0.1 to 1.5, more preferably 0.2 to 1.2, and further preferably 0.4 to 1.0. In a case in which the mixing ratio is in the range of 0.1 to 1.5, the appropriate viscosity can be maintained, the manufacturing suitability is excellent, and the stability of the emulsified liquid is also excellent.

Capsulizing Step

In the capsulizing step, the capsule wall material is polymerized at the interface between the oil phase and the water phase to form the capsule wall, and the microcapsule which encompasses the heat storage material is formed.

˜Polymerization˜

Polymerization is a step of polymerizing the capsule wall material included in the oil phase in the emulsified liquid at the interface with the water phase to form the capsule wall. The polymerization is preferably performed under heating. A reaction temperature in the polymerization is preferably 40° C. to 100° C., and more preferably 50° C. to 80° C. A reaction time of polymerization is preferably about 0.5 to 10 hours, and more preferably about 1 to 5 hours. The polymerization time is shorter as the polymerization temperature is higher, but in a case in which encompassing material and/or capsule wall material which may decompose at a high temperature is used, it is desirable to select a polymerization initiator which acts at a low temperature to polymerize at a relatively low temperature.

In order to prevent the aggregation of the microcapsules in a polymerization step, it is preferable that an aqueous solution (for example, water, an aqueous acetic acid solution, and the like) be further added to reduce the collision probability between the microcapsules, and it is also preferable that sufficient stirring be performed. A dispersing agent for preventing aggregation may be added again in the polymerization step. Further, as needed, a charge adjusting agent such as nigrosin or any other auxiliary agent can be added to the emulsified liquid. These auxiliary agents can be added to the emulsified liquid when forming the capsule wall or in any point in time.

In the present disclosure, in a case in which the heat storage layer is manufactured as will be described below, a microcapsule-containing composition obtained by mixing microcapsules and a dispersion medium may be used. By including the dispersion medium, the microcapsule-containing composition can be easily mixed with other materials in a case of used for various applications.

The dispersion medium can be appropriately selected depending on the intended use of the microcapsule. As the dispersion medium, a liquid component that does not affect the wall material of the microcapsule is preferable. Examples of the liquid component include an aqueous solvent, a viscosity adjuster, a stabilizer, and the like. Examples of the stabilizer include the emulsifier that can be used in the above water phase.

Examples of the aqueous solvent include water, such as ion exchange water, and alcohol.

The content ratio of the dispersion medium in the microcapsule-containing composition can be appropriately selected depending on the applications.

<Binder>

It is preferable that the heat storage layer contain, in addition to the microcapsule, at least one binder outside the microcapsule. Since the heat storage layer contains the binder, durability can be imparted.

As described above, the emulsifier, such as polyvinyl alcohol, may be used in a case in which the microcapsule is manufactured. Therefore, in a case in which the heat storage layer is manufactured by using the microcapsule-containing composition formed by using the emulsifier, the heat storage layer may include the binder derived from the emulsifier.

The binder is not particularly limited as long as it is a polymer which can form a film, and examples thereof include a water-soluble polymer, and an oil-soluble polymer.

The “water-soluble” of the water-soluble polymer means that a dissolved amount of a target substance in 100% by mass of water at 25° C. is 5% by mass or more. As the water-soluble polymer, a polymer having a dissolved amount of 10% by mass or more is preferable.

Further, the “oil-soluble polymer” which will be described below means a polymer other than the “water-soluble polymer” described above.

Examples of the water-soluble polymer include polyvinyl alcohol and its modified product, polyacrylic acid amide and its derivative, a styrene-acrylic acid copolymer, sodium polystyrene sulfonate, an ethylene-vinyl acetate copolymer, a styrene-maleic acid anhydride copolymer, an ethylene-maleic acid anhydride copolymer, an isobutylene-maleic acid anhydride copolymer, a polyvinylpyrrolidone, ethylene-acrylic acid copolymer, a vinyl acetate-acrylic acid copolymer, carboxymethyl cellulose, methyl cellulose, casein, gelatin, a starch derivative, gum arabic, and sodium alginate, and polyvinyl alcohol is preferable.

Examples of the oil-soluble polymer include polymers having heat storage properties disclosed in WO2018/207387A and JP2007-31610A, and a polymer having a long-chain alkyl group (more preferably, a long-chain alkyl group having 12 to 30 carbon atoms) is preferable, and an acrylic resin having a long-chain alkyl group (more preferably, a long-chain alkyl group having 12 to 30 carbon atoms) is more preferable.

Also, in addition to the above, examples of the oil-soluble polymer include a modified product of polyvinyl alcohol, a derivative of polyacrylic acid amide, an ethylene-vinyl acetate copolymer, a styrene-maleic acid anhydride copolymer, an ethylene-maleic acid anhydride copolymer, an isobutylene-maleic acid anhydride copolymer, an ethylene-acrylic acid copolymer, a vinyl acetate-acrylic acid copolymer, and a styrene-acrylic acid copolymer.

Among the above binders, from the viewpoint of making the content ratio of microcapsule in the heat storage layer 70% by mass or more (preferably, 75% by mass or more), the water-soluble polymer is preferable, polyol is more preferable, and polyvinyl alcohol is further preferable. By using the water-soluble polymer, the composition can be prepared, which is suitable for forming the heat storage layer having a sheet shape while maintaining the dispersibility in a case in which an oil in a water type (O/W type) microcapsule liquid using the oil-soluble material such as paraffin as the core material is prepared. Therefore, it is easy to adjust the content ratio of the microcapsule in the heat storage layer to 70% by mass or more.

As the polyvinyl alcohol, a commercially available product on the market may be used, and examples thereof include Kuraray Poval series manufactured by Kuraray Co., Ltd. (for example, Kuraray Poval PVA-217E, Kuraray Poval KL-318, or the like).

Further, in a case in which the binder is polyvinyl alcohol, from the viewpoint of the dispersibility and the film hardness of the microcapsule, the degree of polymerization of polyvinyl alcohol is preferably 500 to 5000, and more preferably 1000 to 3000.

From the viewpoint of easily adjusting the content ratio of the microcapsule in the heat storage layer to 70% by mass or more while maintaining the film hardness of the heat storage layer, the content ratio of the binder in the heat storage layer is preferably 0.1% to 20% by mass, and more preferably 1% to 11% by mass.

The smaller content ratio of the binder is preferable in that the amount of microcapsule to the total mass is increased. Further, in a case in which the content ratio of the binder is in a range not too small, the binder easily protects the microcapsule and maintains the ability of forming the layer which includes the microcapsules, so that microcapsule which has the physical strength can be easily obtained.

In the heat storage layer, the content ratio of the binder to the total mass of the microcapsule is not particularly limited, but it is preferably 15% by mass or less, and more preferably 11% by mass or less, from the viewpoint of more excellent heat storage property of the heat storage layer. The lower limit is not particularly limited, but it is preferably 0.1% by mass or more.

˜Molecular Weight˜

From the viewpoint of the film hardness, a number average molecular weight (Mn) of the binder is preferably 20000 to 300000, and more preferably 20000 to 150000.

The number average molecular weight (Mn) of the binder is a value measured by gel permeation chromatography (GPC).

For the measurement by gel permeation chromatography (GPC), HLC (registered trademark) −8020 GPC (manufactured by Tosoh Corporation) is used as a measuring device, and three TSK gel (registered trademark) Super Multipore HZ-H (4.6 mm ID×15 cm, manufactured by Tosoh Corporation) are used as a column, and THF (tetrahydrofuran) is used as the eluent. As a measurement condition, a sample concentration is 0.45% by mass, a flow rate is 0.35 ml/min, a sample injection amount is 10 a measurement temperature is 40° C., and a refractive index (RI) detector is used.

The calibration curve is produced from 8 samples of “standard sample TSK standard polystyrene” manufactured by Tosoh Corporation: “F-40”, “F-20”, “F-4”, “F-1”, “A-5000”, “A-2500”, “A-1000”, and “n-propylbenzene”.

<Other Components>

The heat storage layer may include other components such as a thermal conductive material, a flame retardant, an ultraviolet absorbing agent, an antioxidant, and a preservative in the outside of the microcapsule, as needed.

The content ratio of the other components which may be outside the microcapsule to the total mass of the heat storage layer is preferably 10% by mass or less, and more preferably 5% by mass or less. Further, the total amount of the microcapsule and the binder to the total mass of the heat storage layer is preferably 80% by mass or more, more preferably 90% to 100% by mass, and further preferably 98% to 100% by mass.

Thermal Conductive Material

It is preferable that the heat storage layer further include the thermal conductive material in the outside the microcapsule. By including the thermal conductive material, the heat radiation property from the heat storage layer after heat storage is excellent, and the cooling efficiency, the cooling rate, the temperature of the heat generating body which generates heat can be satisfactorily maintained.

The “thermal conductivity” of the thermal conductive material means a material having the thermal conductivity of 10 Wm⁻¹K⁻¹ or more. Above all, it is preferable that the thermal conductivity of the thermal conductive material be 50 Wm⁻¹K⁻¹ or more, from the viewpoint of improving the heat radiation property of the heat storage layer.

The thermal conductivity (unit: Wm⁻¹K⁻¹) is a value measured by a flash method at a temperature of 25° C. by a method compliant with Japanese Industrial Standards (JIS) R1611.

Examples of the thermal conductive material include carbon (artificial graphite, carbon black, or the like; 100 to 250), carbon nanotubes (3000 to 5500), metals (for example, silver: 420, copper: 398, gold: 320, aluminum: 236, iron: 84, platinum: 70, stainless steel: 16.7 to 20.9, nickel: 90.9), and silicon (Si; 168).

The numerical values in parentheses described above indicate the thermal conductivity (unit: Wm⁻¹K⁻¹) of each material.

It is preferable that the content ratio of the thermal conductive material in the heat storage layer to the total mass of the heat storage layer be 2% by mass or more. From the viewpoint of the balance between heat storage and heat radiation of the heat storage layer, the content ratio of the thermal conductive material is preferably 10% by mass or less, and more preferably 5% by mass or less.

Flame Retardant

The heat storage layer may further include the flame retardant. In a case in which the heat storage layer include the flame retardant, the flame retardant may be included in any of the inside, the wall portion, or the outside of the microcapsule, but it is preferable that the flame retardant be included outside the microcapsule, from the viewpoint of not changing the characteristics such as heat storage property of the microcapsule and the strength of the capsule wall portion.

The flame retardant is not particularly limited, and a known material can be used. For example, the flame retardant described in “Practical application and technology of flame retardant materials” (published by CMC Publishing Co., Ltd.), and the like can be used, and a halogen-based flame retardant, a phosphorus-based flame retardant, or an inorganic flame retardant is preferably used. In a case in which it is desirable to suppress the mixing of halogen in electronic applications, the phosphorus-based flame retardant or the inorganic flame retardant is preferably used.

Examples of the phosphorus-based flame retardant include phosphate materials such as triphenyl phosphate, tricresyl phosphate, trixylenyl phosphate, cresyl phenyl phosphate, and 2-ethylhexyl diphenyl phosphate, other aromatic phosphate esters, aromatic condensed phosphate esters, polyphosphates, phosphinic acid metal salts, and red phosphorus.

From the viewpoints of the heat storage property and the flame retardance, the content ratio of the flame retardant in the heat storage layer to the total mass of the heat storage layer is preferably 0.1% to 20% by mass, more preferably 1% to 15% by mass, and further preferably 1% to 5% by mass.

It is also preferable to include an auxiliary flame retardant in combination with the flame retardant. Examples of the auxiliary flame retardant include pentaerythritol, phosphorous acid, 22-oxidized tetrazinc 12-boron heptahydrate, and the like.

<Heat Storage Composition>

As described above, the heat storage material included in the heat storage layer may be present in a form not encompassed in the microcapsule. It is preferable that the composition of the heat storage layer in a case in which the heat storage layer does not include the microcapsule which encompasses the heat storage material be the same as the composition of the heat storage layer in a case in which the heat storage layer includes the microcapsule other than a case in which the heat storage composition corresponding to the core material is included instead of the microcapsule.

The heat storage composition in this case may be the same as that described for the core material, including its preferable composition and embodiment. That is, the heat storage composition may include the heat storage material and may include additives such as the solvent and as flame retardant. Details of the heat storage material and the solvent are as described above, and the description thereof is omitted here.

<Physical Property of Heat Storage Layer>

(Thickness)

The thickness of the heat storage layer is preferably 1 to 1000 μm, and more preferably 1 to 500 μm.

The thickness is an average value obtained by observing a cut cross section obtained by cutting the heat storage layer parallel to the thickness direction with a scanning electron microscope (SEM), measuring any 5 points, and averaging the thicknesses of the 5 points.

(Latent Heat Capacity)

From the viewpoints of the high heat storage property and suitability for temperature control of a heat generating body which generates heat, the latent heat capacity of the heat storage layer is preferably 110 J/ml or more, more preferably 135 J/ml or more, and further preferably 145 J/ml or more. The upper limit is not particularly limited, but it is 400 J/ml or less in many cases.

The latent heat capacity is a value calculated from the result of the differential scanning calorimetry (DSC) and the thickness of the heat storage layer.

From the viewpoint of exhibiting a high amount of heat storage in a limited space, the amount of heat storage from in a unit of “J/ml (amount of heat storage per unit volume)” is appropriate, but in a case of the applications to the electronic device, the weight of the electronic device is also important. Therefore, from the viewpoint of exhibiting a high heat storage property in a limited mass, the amount of heat storage in a unit of “J/g (amount of heat storage per unit mass)” may be appropriate. In this case, the latent heat capacity is preferably 140 J/g or more, more preferably 150 J/g or more, further preferably 160 J/g or more, and particularly preferably 190 J/g or more. The upper limit is not particularly limited, but it is 450 J/g or less in many cases.

(Void Ratio)

A ratio of the volume of the microcapsule to the volume of the heat storage layer is preferably 40% by volume or more, more preferably 60% by volume or more, and further preferably 80% by volume or more. The upper limit is not particularly limited, but 100% by volume can be adopted, for example.

In a case in which there is a void in the heat storage layer, the volume of the heat storage layer is large even in a case in which the content of the heat storage material or the microcapsule included in the heat storage layer is the same. Therefore, in a case in which it is desired to reduce the space occupied by the heat storage layer, it is preferable that the heat storage layer does not have a void. From this point, the ratio (void ratio) of the volume of the void in the heat storage layer is preferably 50% by volume or less, more preferably 40% by volume or less, further preferably 20% by volume or less, particularly preferably 15% by volume or less, and most preferably 10% by volume or less. The lower limit is not particularly limited, but 0% by volume can be adopted, for example.

<Manufacturing Method of Heat Storage Layer>

The manufacturing method of the heat storage layer is not particularly limited, and for example, the heat storage layer can be manufactured by applying the dispersion liquid including the microcapsule (or heat storage composition) which encompasses the heat storage material and any component such as the binder, which is used as needed, onto the substrate and drying the liquid. Then, by peeling off a coating film after drying from the substrate, a simple substance of the heat storage layer can be obtained.

Examples of the coating method include a die coating method, an air knife coating method, a roll coating method, a blade coating method, a gravure coating method, and a curtain coating method, and the blade coating method, the gravure coating method, or the curtain coating method is preferable. Further, as an example, there is a method of forming a layer by casting the dispersion liquid including microcapsule which encompasses the heat storage material and the binder.

In the case of the aqueous solvent, it is preferable that the drying be performed in the range of 60° C. to 130° C.

In a step of drying, the layer which includes the microcapsules (for example, the heat storage layer formed of a single layer) may be flattened by using a roller. Alternatively, the operation of applying pressure to the layer which includes microcapsules (for example, the heat storage layer formed of a single layer) by using a device such as a nip roller, a calender, or the like to increase the filling ratio of a microcapsule in the film may be performed.

Further, in order to reduce the void ratio in the heat storage layer, it is preferable to adopt at least one method selected from the group consisting of using the microcapsule which is easily deformed, performing drying gently in a case in which the layer which includes the microcapsules is formed, and performing coating in a plurality of times without forming a thick coating layer at one time.

One of the suitable embodiments of the manufacturing method of a heat storage layer is a method including a step A of mixing a heat storage material, polyisocyanate, at least one active hydrogen-containing compound selected from the group consisting of polyol and polyamine, and an emulsifier to produce a dispersion liquid including a microcapsule which encompasses at least a part of the heat storage material, and a step B of manufacturing a heat storage layer by using the dispersion liquid without substantially adding a binder to the dispersion liquid.

According to the method, since the heat storage layer is manufactured without using the binder, the content ratio of the microcapsule in the heat storage layer can be increased, and as a result, the content ratio of the heat storage material in the heat storage layer can be increased.

That is, the content ratio (encompassing ratio) of the heat storage material which is encompassed in the microcapsule is preferably 95% by mass or more based on the total mass of the heat storage material used in the step A. The upper limit is not particularly limited, but 100% by mass can be adopted, for example.

The description of the material used in the step A (heat storage material, polyisocyanate, at least one active hydrogen-containing compound selected from the group consisting of polyol and polyamine, and the emulsifier) is as described above.

Further, as for the procedure for manufacturing the microcapsule in the step A, the above method can be adopted, for example. As the specific procedure of the step A, it is preferable to perform the step (emulsification step) of dispersing the oil phase including the heat storage material and the capsule wall material (polyisocyanate and active hydrogen-containing compound) in the water phase including the emulsifier to prepare the emulsified liquid, and the step (capsulizing step) of polymerizing the capsule wall material at the interface between the oil phase and the water phase to form the capsule wall, and forming the dispersion liquid including the microcapsule which encompasses the heat storage material.

In the procedure of the step B, no binder is substantially added to the dispersion liquid including the microcapsule produced above. That is, the binder is not substantially added to the dispersion liquid obtained in the step A, and the dispersion liquid is used in manufacturing of the heat storage layer. Where, “without substantially adding the binder” means that the added amount of the binder to the total mass of the microcapsule in the dispersion liquid is 1% by mass or less. Above all, the added amount of the binder is preferably 0.1% by mass or less, and more preferably 0% by mass, based on the total mass of the microcapsule in the dispersion liquid.

In the step B, examples of a procedure for manufacturing the heat storage layer by using the dispersion liquid include, as described above, a procedure for manufacturing by applying and drying the liquid on the substrate.

The suitable embodiment of the manufacturing procedure and manufacturing conditions of the step B are as described in the [Manufacturing Method of Heat Storage Layer] described above.

From the viewpoint of the amount of heat storage, the thickness of the heat storage layer in the heat storage member to the entire thickness of the heat storage member is preferably 50% or more, more preferably 70% or more, further preferably 80% or more, and particularly preferably 90% or more. Further, the upper limit of the thickness of the heat storage layer in the heat storage member is preferably 99.9% or less, and more preferably 99% or less.

[Protective Layer]

The heat storage member according to the present disclosure includes the protective layer having a crosslinking structure. The protective layer is a layer disposed on the heat storage layer. In a case in which the heat storage member includes the substrate, in many cases, the protective layer is disposed on the surface side of the heat storage layer opposite to the substrate.

It is preferable that the protective layer be disposed on the outermost layer of the heat storage member. Further, another layer may be provided on a surface of the protective layer opposite to a surface thereof facing the heat storage layer.

The protective layer of the heat storage member according to the present disclosure has a function of imparting the flame retardance to the heat storage member. Also, the protective layer has a function of protecting the heat storage layer, and thus it is possible to prevent scratches and folding in the process of manufacturing the heat storage member, and to impart handleability.

The protective layer may be disposed so as to be in contact with the heat storage layer, or may be disposed on the heat storage layer via another layer. It is preferable that the protective layer be disposed so as to be in contact with at least one surface of the heat storage layer to manufacture the heat storage member in which the heat storage layer and the protective layer are in contact with each other.

The protective layer has the crosslinking structure. In the present specification, the term “crosslinking structure” means a mesh structure formed by crosslinking. In the heat storage member according to the present disclosure, the protective layer has the crosslinking structure, so that excellent flame retardance is imparted to the heat storage member.

In the present specification, the presence or absence of the crosslinking structure in the protective layer of the heat storage member is evaluated by the following method.

First, the heat storage member is cut out in the stacking direction to produce a sample having a size of 2 cm square. The obtained sample is immersed in 50 ml of water and stirred with a stirrer for 10 minutes, and the sample is extracted. The water solubility of the protective layer is evaluated by visually confirming whether or not the protective layer remains on the surface of the extracted sample.

Next, the heat storage member is cut out in the stacking direction to produce a sample having a size of 2 cm square. The obtained sample is immersed in 50 ml of N,N-dimethylformamide (DMF) and stirred with a stirrer for 10 minutes, and the sample is extracted. The solvent solubility of the protective layer is evaluated by visually confirming whether or not the protective layer remains on the surface of the extracted sample.

As a result of the above test, in a case in which the protective layer remains without almost being dissolved in either water or DMF, it is evaluated that the protective layer of the heat storage member has the crosslinking structure.

The material which configures the protective layer is not particularly limited as long as the material can form the crosslinking structure, and resin is preferable, and resin selected from the group consisting of a resin containing a fluorine atom (hereinafter, also referred to as “fluororesin”) and a siloxane resin is more preferable from the viewpoint of further improving water resistance and flame retardance.

The forming method of the crosslinking structure in the protective layer is not particularly limited, and a resin having the crosslinking structure formed by a known method can be used as a material which configures the protective layer.

For example, in a case in which a fluororesin is used, the crosslinking structure can be formed in the fluororesin by a method in which a fluororesin having a structure including a reactive group such as a hydroxyl group and an amide group is used, a cross-linking agent having a substituent that reacts with the fluororesin is mixed and caused to react with the fluororesin.

Further, in the case of a siloxane resin, a siloxane resin having the crosslinking structure can be produced by hydrolyzing and condensing by using a compound which has 3 or more hydrolyzable groups as a compound represented by Formula (1) described below.

Examples of the fluororesin include a known fluororesin. Examples of the fluororesin include polytetrafluoroethylene, polyvinyl fluoride, polyvinylidene fluoride, polychlorotrifluoroethylene, and polytetrafluoropropylene.

The fluororesin may be a homopolymer obtained by polymerizing the fluorine-containing monomer alone, or may be a copolymer obtained by copolymerizing two or more types of fluorine-containing monomers. Further, the fluororesin may be a copolymer of these fluorine-containing monomer and a monomer other than the fluorine-containing monomer.

Examples of the copolymer include a copolymer of tetrafluoroethylene and tetrafluoropropylene, a copolymer of tetrafluoroethylene and vinylidene fluoride, a copolymer of tetrafluoroethylene and ethylene, a copolymer of tetrafluoroethylene and propylene, a copolymer of tetrafluoroethylene and vinyl ether, a copolymer of tetrafluoroethylene and perfluorovinyl ether, a copolymer of chlorotrifluoroethylene and vinyl ether, and a copolymer of chlorotrifluoroethylene and perfluorovinyl ether.

Examples of the fluororesin include Obbligato (registered trademark) SW0011F (manufactured by AGC COAT-TECH Co., Ltd.); SIFCLEAR-F101 and F102 (manufactured by JSR Corporation); KYNAR AQUATEC (registered trademark) ARC and FMA-12 (both manufactured by Arkema).

The siloxane resin is a polymer which has a repeating unit having a siloxane skeleton, and a hydrolysis condensate of a compound represented by Formula (1) as follows is preferable.

Formula(1)

Si(X)ₙ(R)₄₋ₙ (1)

X indicates a hydrolyzable group. Examples of the hydrolyzable group include an alkoxy group, a halogen group, an acetoxy group, and an isocyanate group.

R indicates a non-hydrolyzable group. Examples of the non-hydrolyzable group include an alkyl group (for example, a methyl group, an ethyl group, and a propyl group), an aryl group (for example, a phenyl group, a tolyl group, and a mesityl group), an alkenyl group (for example, a vinyl group and an allyl group), haloalkyl group (for example, a γ-chloropropyl group), an aminoalkyl group (for example, a γ-aminopropyl group and γ-(2-aminoethyl) aminopropyl group), an epoxy alkyl group (for example, a γ-glycidoxypropyl group and a β-(3,4-epoxycyclohexyl) ethyl group), a γ-mercapto alkyl group, a (meth)acryloyloxyalkyl group (a γ-methacryloyloxypropyl group), and a hydroxyalkyl group (for example, a γ-hydroxypropyl group).

n indicates an integer of 1 to 4, and is preferably 3 or 4.

The hydrolysis condensate described above is intended to be a compound obtained by hydrolyzing the hydrolyzable group in the compound represented by Formula (1) and condensing the obtained hydrolyzate. The hydrolysis condensate described above may be a condensate in which all of the hydrolyzable groups are hydrolyzed, and all of the hydrolyzates are condensed (full hydrolysis condensate), or may be a condensate in which a part of the hydrolyzable group is hydrolyzed, and a part of the hydrolyzate is condensed (partial hydrolysis condensate). That is, the hydrolysis condensate may be a full hydrolysis condensate, a partial hydrolysis condensate, or a mixture thereof.

In a case in which the protective layer includes the siloxane resin, from the viewpoint of further suppressing the fissuring on the surface, it is preferable that the siloxane resin be the hydrolysis condensate obtained by hydrolyzing a mixture obtained by mixing two or more types of compounds represented by Formula (1).

The ratio of the usage amount of two or more types of the compounds represented by Formula (1) is not particularly limited, but the ratio of the amount of the most abundant compound to the amount of the second most abundant compound is preferably 100/1 or less, and more preferably 20/1 or less. The lower limit value is not particularly limited and need only be 1/1 or more.

As the protective layer, for example, a layer which includes a known hard coating agent or a hard coating film as disclosed in JP2018-202696A, JP2018-183877A, and JP2018-111793A may be used. Also, from the viewpoint of the heat storage property, the protective layer which includes a polymer having the heat storage property as disclosed in WO2018/207387A and JP2007-031610A may be used.

The protective layer may include components other than the resin. Examples of other components include a flame retardant, a curing agent, a thermal conductive material, an ultraviolet absorbing agent, an antioxidant, and a preservative.

The flame retardant is not particularly limited, and a known material can be used. For example, the flame retardant described in “Practical application and technology of flame retardant materials” (published by CMC Publishing Co., Ltd.) can be used, and a halogen-based flame retardant, a flame retardant containing the phosphorus atom (hereinafter, also referred to as “phosphorus-based flame retardant”), or an inorganic flame retardant is preferably used. In a case in which it is desirable to suppress the mixing of halogen in electronic applications, the phosphorus-based flame retardant or the inorganic flame retardant is preferably used.

Examples of the phosphorus-based flame retardant include a phosphate material such as triphenyl phosphate, tricresyl phosphate, trixylenyl phosphate, cresyl phenyl phosphate, and 2-ethylhexyl diphenyl phosphate, other aromatic phosphate esters, aromatic condensed phosphate esters, polyphosphates, phosphinic acid metal salts, red phosphorus, and the like.

As the flame retardant, an inorganic particle such as silica may be used. The amount and type of the inorganic particle can be adjusted depending on the surface shape and/or film quality. The size of the inorganic particle is preferably 0.01 to 1 μm, more preferably 0.05 to 0.2 μm, and further preferably 0.1 to 0.1 μm. The content ratio of the inorganic particles to the total mass of the protective layer is preferably 0.1% to 50% by mass, and more preferably 1% to 40% by mass.

From the viewpoints of the amount of heat storage and the flame retardance, the content ratio of the flame retardant in the protective layer to the total mass of the protective layer is preferably 0.1% to 20% by mass, more preferably 1% to 15% by mass, and further preferably 1% to 5% by mass.

It is also preferable to include an auxiliary flame retardant in combination with the flame retardant. Examples of the auxiliary flame retardant include pentaerythritol, phosphorous acid, and 22-oxidized tetrazinc 12-boron heptahydrate.

It is preferable that the protective layer have the flexibility which is hard to be fissured and a hard coat property which is hard to be scratched. From these points, it is preferable that the composition for forming the protective layer include at least the curing agent, the cross-linking agent, or a thermal initiator, or a photoinitiator, and more preferable that the composition for forming the protective layer include a curing agent.

Examples of the curing agent included in the composition for forming the protective layer include a reactive monomer, oligomer, and polymer which is cured by heat or radiation (for example, an acrylic resin, an urethane resin, and rubber).

The content of the curing agent in the protective layer to the total mass of the protective layer is preferably 5% to 50% by mass, and more preferably 10% to 40% by mass.

The thickness of the protective layer is not particularly limited, but is preferably 50 μm or less, more preferably 25 μm or less, further preferably 15 μm or less, and particularly preferably 10 μm or less from the viewpoint of excellent heat storage property and fissuring characteristic of the heat storage member. The lower limit value is not particularly limited, but is preferably 0.1 μm or more, more preferably 1 μm or more, and further preferably more than 3 μm from the viewpoint that the heat storage member is more excellent in flame retardance.

Further, from the viewpoint of the excellent heat storage property of the heat storage member, the ratio of the thickness of the protective layer to the thickness of the heat storage layer is preferably 1/10 or less, more preferably 1/20 or less, and further preferably 1/40 or less. The lower limit value is not particularly limited, but is preferably 1/1000 or more, and more preferably 1/200 or more from the viewpoint that the heat storage member is more excellent in flame retardance.

The thickness of the protective layer is an average value obtained by observing the cut cross section of the protective layer cut in parallel to the thickness direction with SEM, measuring any 5 points, and averaging the thicknesses of the 5 points.

It is preferable that no fissuring be present on the surface of the protective layer opposite to the surface thereof facing the heat storage layer. Here, “no fissuring is present” means a state in which no fissuring can be observed in a case in which the surface of the protective layer is observed by using SEM at a magnification of 200 times. The fissuring characteristic of the protective layer can be adjusted by adjusting the ratio of cross-linking in the protective layer based on the amount of curing agent and the number of cross-linking points of the polymer precursor to be cured. Further, the occurrence of fissuring can be suppressed by thinning the film thickness of the protective layer. By forming a flexible protective layer in which no fissuring is present, the heat storage member can be applied to the roll type.

The forming method of the protective layer is not particularly limited, and a known method can be adopted. For example, there are a method in which the composition for forming the protective layer including a resin or a precursor thereof is brought into contact with the heat storage layer, and the coating film is formed on the heat storage layer, and a curing treatment is performed on the coating film as needed, and a method of adhering the protective layer to the heat storage layer.

The resin included in the composition for forming the protective layer is as above. Examples of the composition for forming the protective layer include a composition including at least one selected from the group consisting of a resin containing a fluorine atom and a siloxane resin or a precursor thereof.

The precursor of the resin means a component that becomes a resin by curing treatment, and examples thereof include a compound represented by Formula (1) above.

The composition for forming the protective layer may include the solvent (for example, water and an organic solvent), as needed. Further, it is more preferable that the composition for forming the protective layer include the flame retardant (more preferably, the flame retardant containing a phosphorus atom).

The method in which the composition for forming the protective layer is brought into contact with the heat storage layer is not particularly limited, and for example, there are a method of applying the composition for forming the protective layer on the heat storage layer, a method of immersing the heat storage layer in the composition for forming the protective layer, and a method of applying the composition for forming the protective layer including the binder on the heat storage layer to form the coating film.

In the method of applying the composition for forming the protective layer including a binder to form the coating film, it is preferable that the composition for forming the protective layer further include the solvent. In a case in which the composition for forming the protective layer includes the solvent, it is preferable to perform the drying step after forming the coating film to volatilize the solvent from the coating film. Further, from the viewpoint of improving the coatability and the flame retardance, the composition for forming the protective layer which includes the binder may further include additives such as the surfactant and the flame retardant.

Examples of the method of applying the composition for forming the protective layer include a method of using a known coating device such as a dip coater, a die coater, a slit coater, a bar coater, an extrusion coater, a curtain flow coater, spray coating, and the like, and a printing device such as gravure printing, screen printing, offset printing, inkjet printing, and the like.

[Other layers]

The heat storage member may include a layer other than the heat storage layer and the protective layer.

<Substrate>

The heat storage member may further include the substrate, and preferably further includes the substrate.

Examples of the substrate include a resin substrate such as polyester (for example, polyethylene terephthalate and polyethylene naphthalate), polyolefin (for example, polyethylene and polypropylene), and polyurethane, a glass substrate, and a metal substrate. It is also preferable to add a function of improving the thermal conductivity in a plane direction or a film thickness direction and quickly diffusing heat from a heat generating portion to a heat storage portion to the substrate. In that case, it is preferable that the metal substrate and the thermal conductive material such as a graphene sheet be used as the substrate.

The thickness of the substrate is not particularly limited, and can be appropriately selected depending on the purpose and the case. It is preferable the thickness of the substrate be thick from the viewpoint of the handleability, and it is preferable that the thickness be thin from the viewpoint of the amount of heat storage (content ratio of the microcapsule in the heat storage layer).

The thickness of the substrate is preferably 1 to 100 μm, more preferably 1 to 25 μm, and further preferably 3 to 15 μm.

It is preferable that a surface of the substrate be subjected to surface treatment of the substrate for a purpose of improving the adhesiveness to the heat storage layer. Examples of a surface treatment method include a method such as corona treatment, plasma treatment, providing of a thin layer which is an easy adhesion layer, and the like.

The easy adhesion layer has hydrophilicity-hydrophobicity and affinity with the materials of both the heat storage layer and the substrate, and preferably has adhesiveness. The preferable material which configures the easy adhesion layer differs depending on the material of the heat storage layer.

The material which configures the easy adhesion layer is not particularly limited, but styrene-butadiene rubber, an urethane resin, an acrylic resin, a silicone resin, or a polyvinyl resin is preferable. In a case in which the substrate includes polyethylene terephthalate (PET), and the heat storage layer includes at least one selected from the group consisting of polyurethane, polyurea, polyurethane urea, and polyvinyl alcohol, in some cases, for example, styrene-butadiene rubber or an urethane resin is preferably used as the material which configures the easy adhesion layer.

From the viewpoint of the film hardness and adhesiveness, it is preferable that the cross-linking agent be introduced into the easy adhesion layer. It is considered that an appropriate amount of the cross-linking agent is present to prevent the film itself from aggregation breaking to be easily peeled off, and to prevent the film from being too hard from the viewpoint of the adhesiveness.

The easy adhesion layer may include two or more types of materials including a material that easily adheres to the substrate and a material that easily adheres to the heat storage layer. Further, the easy adhesion layer may be a stacked body of two or more layers including a layer that easily adheres to the substrate and a layer that easily adheres to the heat storage layer.

It is preferable that the thickness of the easy adhesion layer be thick from the viewpoint of adhesiveness, but in a case in which the easy adhesion layer is too thick, the amount of heat storage of the heat storage member as a whole is decreased. Therefore, the thickness of the easy adhesion layer is preferably 0.1 to 5 μm, and more preferably 0.5 to 2 μm.

<Adhesion Layer>

The adhesion layer may be provided on the side of the substrate opposite to the side provided with the heat storage layer.

The adhesion layer is not particularly limited, and can be appropriately selected depending on the intended purpose, and examples thereof include a layer which includes a known pressure sensitive adhesive (also referred to as a pressure-sensitive adhesive layer) or a layer which includes an adhesive (also referred to as an adhesive layer).

Examples of the pressure sensitive adhesive include an acrylic pressure sensitive adhesive, a rubber-based pressure sensitive adhesive, and a silicone-based pressure sensitive adhesive. Further, examples of the pressure sensitive adhesive also include the acrylic pressure sensitive adhesive, the ultraviolet (UV) curing pressure sensitive adhesive, the silicone pressure sensitive adhesive described in “Characteristic evaluation of peeling paper/peeling film and pressure sensitive adhesive tape and its control technology”, published by Johokiko Co., Ltd., 2004, Chapter 2.

The acrylic pressure sensitive adhesive refers to a pressure sensitive adhesive including a polymer ((meth)acrylic polymer) of a (meth)acrylic monomer.

Further, the pressure-sensitive adhesive layer may include a viscosity imparting agent.

Examples of the adhesive include an urethane resin adhesive, a polyester adhesive, an acrylic resin adhesive, an ethylene vinyl acetate resin adhesive, a polyvinyl alcohol adhesive, a polyamide adhesive, and a silicone adhesive. From the viewpoint of the higher adhesive strength, the urethane resin adhesive or the silicone adhesive is preferable.

The forming method of the adhesion layer is not particularly limited, and examples thereof include a forming method of transferring the adhesion layer onto the substrate, and a forming method of applying a composition including the pressure sensitive adhesive or the adhesive onto the substrate.

From the viewpoint of the pressure sensitive adhesive strength, handleability, and the amount of heat storage, the thickness of the adhesion layer is preferably 0.5 to 100 μm, more preferably 1 to 25 μm, and further preferably 1 to 15 μm.

A peeling sheet may adhere to a surface of the adhesion layer opposite to a side facing the substrate. Since the peeling sheet adheres, for example, in a case in which the microcapsule dispersion liquid is applied on the substrate, the handleability in a case of the thin thicknesses of the substrate and the adhesion layer can be improved.

The peeling sheet is not particularly limited, and for example, a peeling sheet in which a peeling material, such as silicone, is attached on a support, such as PET or polypropylene, can be suitably used.

[Physical Property of Heat Storage Member]

<Latent Heat Capacity>

From the viewpoints of the high heat storage property and suitability for temperature control of a heat generating body which generates heat, the latent heat capacity of the heat storage member is preferably 105 J/ml or more, more preferably 120 J/ml or more, and further preferably 130 J/ml or more. The upper limit is not particularly limited, but is 400 J/ml or less in many cases.

The latent heat capacity is a value calculated from the result of the differential scanning calorimetry (DSC) and the thickness of the heat storage member.

From the viewpoint of exhibiting a high amount of heat storage in a limited space, the amount of heat storage from in a unit of “J/ml (amount of heat storage per unit volume)” is appropriate, but in a case of the applications to the electronic device, the weight of the electronic device is also important. Therefore, from the viewpoint of exhibiting a high heat storage property in a limited mass, the amount of heat storage in a unit of “J/g (amount of heat storage per unit weight)” may be appropriate. In this case, the latent heat capacity of the heat storage member is preferably 120 J/g or more, more preferably 140 J/g or more, further preferably 150 J/g or more, and particularly preferably 160 J/g or more. The upper limit is not particularly limited, but it is 450 J/g or less in many cases.

<Tensile Breaking Elongation>

From the viewpoint of being capable of providing the heat storage member as a roll type, it is preferable that the tensile strength of the heat storage member and the elongation ratio at the time of tensile breaking be large. The elongation ratio at the time of tensile breaking is preferably 10% or more, more preferably 20% or more, and further preferably 30% or more. The upper limit is not particularly limited, but is 500% or less in many cases. The tensile strength is preferably 1 MPa or more, more preferably 5 MPa or more, and further preferably 10 MPa or more. The upper limit is not particularly limited, but is 100 MPa or less in many cases, and preferably 50 MPa or less.

The tensile strength of the heat storage member and the elongation ratio at the time of tensile breaking are measured according to the method described in JIS K6251. Specifically, the heat storage sheet is cut out into a dumbbell-shaped No. 2 type, and a test piece with two marked lines is produced with an initial distance between marked lines of 20 mm. This test piece is attached to a tensile tester and pulled at a speed of 200 mm/min to breaking. At this time, the maximum force (N) until breaking and the distance (mm) between marked lines at the time of breaking are measured, and the tensile strength and the elongation ratio at the time of tensile breaking are calculated by the following equation.

The tensile strength TS (MPa) is calculated by the following equation.

TS=Fm/Wt

Fm: maximum force (N)

W: width of parallel portion (mm)

t: thickness of parallel portion (mm)

The elongation ratio Eb (%) at the time of tensile breaking is calculated by the following equation.

Eb=(Lb-L0)/L0×100

Lb: distance (mm) between marked lines at the time of breaking

L0: initial distance (mm) between marked lines

[Electronic Device]

The electronic device includes the heat storage member described above. The electronic device may include a member other than the heat storage member described above. Examples of other members include the heat generating body, a thermally conductive material, a heat pipe, a vapor chamber, the adhesive, and the substrate. The electronic device preferably includes at least one of the heat generating body or the thermally conductive material, and more preferably include the heat generating body.

One of the suitable embodiments of the electronic device is an embodiment including the heat storage member, the thermally conductive material which is disposed on the heat storage member, and the heat generating body which is disposed on the surface side of the thermally conductive material opposite to the heat storage member.

In a case in which the heat storage member described above includes the protective layer, one of the suitable embodiments of the electronic device is an embodiment including the heat storage member described above, a metal plate which is disposed on a surface side of the heat storage member opposite to the protective layer, and the heat generating body which is disposed on a surface side of the metal plate opposite to the heat storage member. Stated another way, it is preferable that the protective layer, the heat storage layer, the metal plate, and the heat generating body be stacked in this order.

The heat storage members (heat storage layer and protective layer) are as described above.

[Heat Generating Body]

The heat generating body is a member which may generate heat, which is included in the electronic device, and is, for example, systems on a chip (SoC) such as a central processing unit (CPU), a graphics processing unit (GPU), a static random access memory (SRAM), and a radio frequency (RF) device, a camera, a LED package, power electronics, and a battery (in particular, lithium-ion secondary battery).

The heat generating body may be disposed so as to be in contact with the heat storage member, or may be disposed on the heat storage member via another layer (for example, the thermally conductive material which will be described below).

[Thermally Conductive Material]

It is preferable that the electronic device further include the thermally conductive material.

The thermally conductive material refers to a material which has a function of conducting heat which is generated from the heat generating body to another medium.

The “thermal conductivity” of the thermally conductive material means a material having the thermal conductivity of 10 Wm⁻¹K⁻¹ or more. The thermal conductivity (unit: Wm⁻¹K⁻¹) is a value measured by a flash method at a temperature of 25° C. by a method compliant with Japanese Industrial Standards (JIS) R1611.

Examples of the thermally conductive material include the metal plate, the heat dissipation sheet, and silicone grease, and the metal plate or the heat dissipation sheet is preferable.

It is preferable that the electronic device include the heat storage member described above, the thermally conductive material which is disposed on the heat storage member, and the heat generating body which is disposed on the surface side of the thermally conductive material opposite to the heat storage member. Further, it is more preferable that the electronic device include the heat storage member described above, the metal plate which is disposed on the heat storage member, and the heat generating body which is disposed on the surface side of the metal plate opposite to the heat storage member.

In a case in which the heat storage member described above includes the protective layer, one of the suitable embodiments of the electronic device is an embodiment including the heat storage member described above, a metal plate which is disposed on a surface side of the heat storage member opposite to the protective layer, and the heat generating body which is disposed on a surface side of the metal plate opposite to the heat storage member. Stated another way, it is preferable that the protective layer, the heat storage layer, the metal plate, and the heat generating body be stacked in this order.

<Heat Dissipation Sheet>

The heat dissipation sheet is a sheet which has a function of conducting heat which is generated from the heat generating body to another medium, and it is preferable that a heat dissipation material be provided. Examples of the heat dissipation material include carbon, metal (for example, silver, copper, aluminum, iron, platinum, stainless steel, nickel, and the like), and silicon.

Examples of the heat dissipation sheet include a copper foil sheet, a metal plate, a metal coating film resin sheet, a metal-containing resin sheet, and a graphene sheet, and the graphene sheet is preferable. The thickness of the heat dissipation sheet is not particularly limited, but it is preferably 10 to 500 μm and more preferably 20 to 300 μm.

[Heat Pipe, Vapor Chamber]

The electronic device may further include a heat transport member selected from the group consisting of the heat pipe and the vapor chamber.

Both the heat pipe and the vapor chamber are formed of the metal, and comprise at least a member which has a hollow structure and a working fluid which is a heat transfer medium enclosed in the internal space, in which the working fluid evaporates (vaporizes) in a high temperature portion (evaporation portion) to absorb heat, and the vaporized working fluid is condensed in a low temperature portion (condensing portion) to release heat. The heat pipe and the vapor chamber have a function of transporting heat from a member in contact with the high temperature portion to a member in contact with the low temperature portion due to a phase change of the working fluid inside.

In a case in which the electronic device includes the heat storage member and the heat transport member selected from the group consisting of the heat pipe and the vapor chamber, it is preferable that the heat storage member and the heat pipe or the vapor chamber be in contact with each other, and it is more preferable that the heat storage member be in contact with the low temperature portion of the heat pipe or the vapor chamber.

Further, in a case in which the electronic device includes the heat storage member and the heat transport member selected from the group consisting of the heat pipe and the vapor chamber, it is preferable that the phase change temperature of the heat storage material included in the heat storage layer, and the temperature range in which the heat pipe or the vapor chamber is operated be overlapped. The temperature range in which the heat pipe or the vapor chamber is operated includes, for example, the temperature range in which the working fluid can change a phase in each inside.

The materials which configure the heat pipe and the vapor chamber are not particularly limited as long as it is a material which has high thermal conductivity, and examples thereof include a metal such as copper and aluminum.

Examples of the working fluid enclosed in the internal space of the heat pipe and the vapor chamber include water, methanol, ethanol, and CFC substitutes, which are appropriately selected and used depending on the temperature range of the applied electronic device.

[Other Members]

The electronic device may include members other than the protective layer, the heat storage layer, the metal plate, and the heat generating body. Examples of other members include the heat dissipation sheet, the substrate, and the adhesion layer. The substrate and the adhesion layer are as above.

The electronic device may have at least one member selected from the group consisting of the heat dissipation sheet, the substrate, and the adhesion layer between the heat storage layer and the metal plate. In a case in which two or more members among the heat dissipation sheet, the substrate, and the adhesion layer are disposed between the heat storage layer and the metal plate, the substrate, the adhesion layer, and the heat dissipation sheet are preferably disposed in this order from the heat storage layer side to the metal plate side.

Further, the electronic device may have the heat dissipation sheet between the metal plate and the heat generating body.

### EXAMPLES

Hereinafter, the present invention will be described more specifically with reference to Examples. However, the present invention is not limited to the following Examples as long as the gist of the present invention is not exceeded. Unless otherwise noted, “parts” and “%” are based on mass.

The particle diameter D50 and a wall thickness of the microcapsule were measured by the method described above.

### Example 1

(Preparation of Composition for Forming Heat Storage Layer)

A solution A1 to which 120 parts by mass of ethyl acetate were added was obtained by heating and dissolving 72 parts by mass of icosane (latent heat storage material; an aliphatic hydrocarbon having a melting point of 37° C. and 20 carbon atoms) at 60° C.

A solution B1 was obtained by adding 0.05 parts by mass of N,N,N′,N′-tetrakis(2-hydroxypropyl)ethylenediamine (Adeka Polyether EDP-300, manufactured by ADEKA CORPORATION) to the solution A1 being stirred.

A solution C1 was obtained by adding 4 parts by mass of trimethylolpropane adduct (Burnock D-750, manufactured by DIC Corporation) of tolylene diisocyanate dissolved in 1 part by mass of methyl ethyl ketone to the solution B1 being stirred.

The solution C1 was added to a solution obtained by dissolving 7.4 parts by mass of polyvinyl alcohol (Kuraray Poval (registered trademark) KL-318 (manufactured by Kuraray Co., Ltd.; polyvinyl alcohol (PVA)) as the emulsifier in 140 parts by mass of water, and the mixture was emulsified and dispersed. 250 parts by mass of water were added to the emulsified liquid after emulsification and dispersion, the mixture was heated to 70° C. while stirring the obtained liquid, and then cooled to 30° C. after continuing stirring for 1 hour. Water was further added to the cooled liquid to adjust the concentration, and an icosane encompassing microcapsule dispersion liquid which has a polyurethane urea capsule wall was obtained.

A concentration of solid contents of the icosane encompassing microcapsule dispersion liquid was 14% by mass.

The mass of the capsule wall of the icosane encompassing microcapsule to the mass of the encompassed icosane was 6% by mass.

The volume-based median diameter D50 of the microcapsule was 20 μm. The thickness 8 of the capsule wall of the microcapsule was 0.1 μm.

By adding and mixing 1.5 parts by mass of a side chain alkylbenzene sulfonic acid amine salt (NEOGEN T, manufactured by DKS Co., Ltd.), 0.15 parts by mass of 1,2-bis(3,3,4,4,5,5,6,6,6-nonafluorohexyloxycarbonyl) sodium ethanesulfonate (W-AHE, manufactured by FUJIFILM Corporation), and 0.15 parts by mass of polyoxyalkylene alkyl ether (Noigen LP-90, manufactured by DKS Co., Ltd.) to 1000 parts by mass of the obtained microcapsule dispersion liquid, and a composition 1 for forming a heat storage layer was prepared.

(Manufacturing of Polyethylene Terephthalate (PET) Substrate (A) with Easy Adhesion Layer and Pressure-Sensitive Adhesive Layer)

An optical pressure sensitive adhesive sheet MO-3015 (thickness: 5 μm) manufactured by LINTEC Corporation was attached to the PET substrate which has a thickness of 12 μm to form the pressure-sensitive adhesive layer.

An aqueous solution in which Nipol Latex LX407C4E (manufactured by Zeon Corporation), Nipol Latex LX407C4C (manufactured by Zeon Corporation), and Aquabrid EM-13 (manufactured by Daicel Fine Chem Ltd.) were mixed and dissolved such that the concentration of solid contents was 22:77.5:0.5 (mass-based) was applied on the surface of the PET substrate opposite to the surface provided with the pressure-sensitive adhesive layer. The obtained coating film was dried at 115° C. for 2 minutes to form the easy adhesion layer formed of a styrene-butadiene rubber resin which has a thickness of 1.3 μm and manufacture a PET substrate (A) with the easy adhesion layer and the pressure-sensitive adhesive layer.

(Preparation of Composition A for Forming Protective Layer)

A composition A for forming the protective layer was prepared by mixing and dissolving 22.3 parts by mass of pure water, 32.5 parts by mass of ethanol, 3.3 parts by mass of acetic acid, and 41.9 parts by mass of KR-516 (manufactured by Shin-Etsu Chemical Co., Ltd., siloxane oligomer) and stirring the mixed solution for 12 hours.

(Manufacturing of Heat Storage Member)

The composition 1 for forming the heat storage layer prepared above was applied on the surface of the easy adhesion layer side of the PET substrate (A) with the easy adhesion layer and the pressure-sensitive adhesive layer by a bar coater such that the mass after drying was 133 g/m², and the coating film was dried to form a heat storage layer 1 having a thickness of 190 μm.

Next, the composition A for forming the protective layer was applied on the surface of the heat storage layer 1 on the side opposite to the surface in contact with the easy adhesion layer, and the coating film was dried at 100° C. for 10 minutes to form a protective layer A having a thickness of 8 μm.

As a result, a heat storage member 1 in which the pressure-sensitive adhesive layer, the PET substrate (A), the easy adhesion layer, the heat storage layer 1, and the protective layer A are stacked in this order was manufactured.

### Example 2

A composition B for forming the protective layer was prepared by mixing 35.8 parts by mass of KYNAR Aquatec ARC (manufactured by Arkema, 44% by mass of concentration of solid contents; fluorine-containing resin), 31.6 parts by mass of Epocros WS-700 (manufactured by Nippon Shokubai Co., Ltd., 25% of concentration of solid contents; curing agent), 29.6 parts by mass of Taien E (manufactured by Taihei Chemical Industrial Co., Ltd.; flame retardant), and 3.0 parts by mass of Noigen LP-70 (manufactured by DKS Co., Ltd. (diluted in an aqueous solution which has 2% by mass of concentration of solid contents); surfactant).

A heat storage member 2 in which the pressure-sensitive adhesive layer, the PET substrate (A), the easy adhesion layer, the heat storage layer 1, and a protective layer B having a thickness of 8 μm are stacked in this order was manufactured according to the method described in Example 1 except that the composition B for forming the protective layer obtained as above was used instead of the composition A for forming the protective layer and the coating film of the composition B for forming the protective layer was dried at 100° C. for 3 minutes.

### Example 3

A composition C for forming the protective layer was prepared by dissolving 30.0 parts by mass of X-12-1098 (manufactured by Shin-Etsu Chemical Co., Ltd.; silane coupling agent) and 2.0 parts by mass of Noigen LP-70 (manufactured by DKS Co., Ltd. (diluted in an aqueous solution which has 2% of a concentration of solid contents); surfactant) in 68.0 parts by mass of pure water.

A heat storage member 3 in which the pressure-sensitive adhesive layer, the PET substrate (A), the easy adhesion layer, the heat storage layer 1, and a protective layer C having a thickness of 1 μm are stacked in this order was manufactured according to the method described in Example 1 except that the composition C for forming the protective layer obtained as above was used instead of the composition A for forming the protective layer and the coating film of the composition C for forming the protective layer was dried at 100° C. for 3 minutes.

### Example 4

30.0 parts by mass of X-12-1098 (manufactured by Shin-Etsu Chemical Co., Ltd.) and 2.0 parts by mass of Noigen LP-70 (manufactured by DKS Co., Ltd. (used by being diluted in 2% by mass the concentration of solid contents); surfactant) were dissolved in 68.0 parts by mass of pure water, and then 1 mol/L of sodium hydroxide aqueous solution was added to adjust pH of the mixed solution to 9.0, and the mixed solution was stirred for 1 hour. Then, 1 mol/L of hydrochloric acid water was added to adjust the pH of the mixed solution to 3.2 to prepare a composition D for forming the protective layer.

A heat storage member 4 in which the pressure-sensitive adhesive layer, the PET substrate (A), the easy adhesion layer, the heat storage layer 1, and a protective layer D having a thickness of 3 μm are stacked in this order was manufactured according to the method described in Example 1 except that the composition D for forming the protective layer obtained as above was used instead of the composition A for forming the protective layer and the coating film of the composition D for forming the protective layer was dried at 100° C. for 3 minutes.

### Example 5

A heat storage member 5 in which the pressure-sensitive adhesive layer, the PET substrate (A), the easy adhesion layer, the heat storage layer 1, and a protective layer E having a thickness of 2 μm are stacked in this order was manufactured according to the method described in Example 2 except that the protective layer E having a thickness of 2 μm was formed by using the composition B for forming the protective layer.

### Example 6

A heat storage member 6 in which the pressure-sensitive adhesive layer, the PET substrate (A), the easy adhesion layer, the heat storage layer 1, and a protective layer F having a thickness of 5 μm are stacked in this order was manufactured according to the method described in Example 2 except that the protective layer F having a thickness of 5 μm was formed by using the composition B for forming the protective layer.

### Example 7

A heat storage member 7 in which the pressure-sensitive adhesive layer, the PET substrate (A), the easy adhesion layer, the heat storage layer 1, and a protective layer G having a thickness of 15 μm are stacked in this order was manufactured according to the method described in Example 2 except that the protective layer G having a thickness of 15 μm was formed by using the composition B for forming the protective layer.

### Example 8

A composition E for forming the protective layer was prepared by dissolving 0.4 part by mass of acetic acid, 27.0 parts by mass of X-12-1098 (manufactured by Shin-Etsu Chemical Co., Ltd.), 3.0 parts by mass of KBE-04 (manufactured by Shin-Etsu Chemical Co., Ltd.; silane coupling agent) and 1.5 parts by mass of Noigen LP-70 (manufactured by DKS Co., Ltd. (used by being diluted in 2% by mass of concentration of solid contents); surfactant) in 68.1 parts by mass of pure water, and stirring the mixed solution for 2 hours.

A heat storage member 8 in which the pressure-sensitive adhesive layer, the PET substrate (A), the easy adhesion layer, the heat storage layer 1, and a protective layer H having a thickness of 3 μm are stacked in this order was manufactured according to the method described in Example 1 except that the composition E for forming the protective layer obtained as above was used instead of the composition A for forming the protective layer and the coating film of the composition E for forming the protective layer was dried at 100° C. for 3 minutes.

### Example 9

A heat storage member 9 in which the pressure-sensitive adhesive layer, the PET substrate (A), the easy adhesion layer, the heat storage layer 1, and a protective layer I having a thickness of 6 μm are stacked in this order was manufactured according to the method described in Example 8 except that the protective layer I having a thickness of 6 μm was formed by using the composition E for forming the protective layer.

### Example 10

A composition F for forming the protective layer was prepared by dissolving 0.4 part by mass of acetic acid, 24.0 parts by mass of X-12-1098 (manufactured by Shin-Etsu Chemical Co., Ltd.), 6.0 parts by mass of KBE-04 (manufactured by Shin-Etsu Chemical Co., Ltd.; silane coupling agent) and 1.5 parts by mass of Noigen LP-70 (manufactured by DKS Co., Ltd. (used by being diluted in 2% by mass of concentration of solid contents); surfactant) in 68.1 parts by mass of pure water, and stirring the mixed solution for 2 hours.

A heat storage member 10 in which the pressure-sensitive adhesive layer, the PET substrate (A), the easy adhesion layer, the heat storage layer 1, and a protective layer J having a thickness of 3 μm are stacked in this order was manufactured according to the method described in Example 1 except that the composition F for forming the protective layer obtained as above was used instead of the composition A for forming the protective layer and the coating film of the composition F for forming the protective layer was dried at 100° C. for 3 minutes.

### Example 11

A heat storage member 11 in which the pressure-sensitive adhesive layer, the PET substrate (A), the easy adhesion layer, the heat storage layer 1, and a protective layer K having a thickness of 6 μm are stacked in this order was manufactured according to the method described in Example 10 except that the protective layer K having a thickness of 6 μm was formed by using the composition F for forming the protective layer.

### Example 12

A composition G for forming the protective layer was prepared by dissolving 0.4 part by mass of acetic acid, 21.0 parts by mass of X-12-1098 (manufactured by Shin-Etsu Chemical Co., Ltd.), 9.0 parts by mass of KBE-04 (manufactured by Shin-Etsu Chemical Co., Ltd.; silane coupling agent) and 1.5 parts by mass of Noigen LP-70 (manufactured by DKS Co., Ltd. (used by being diluted in 2% by mass of concentration of solid contents); surfactant) in 68.1 parts by mass of pure water, and stirring the mixed solution for 2 hours.

A heat storage member 12 in which the pressure-sensitive adhesive layer, the PET substrate (A), the easy adhesion layer, the heat storage layer 1, and a protective layer L having a thickness of 3 μm are stacked in this order was manufactured according to the method described in Example 1 except that the composition G for forming the protective layer obtained as above was used instead of the composition A for forming the protective layer and the coating film of the composition G for forming the protective layer was dried at 100° C. for 3 minutes.

### Example 13

A heat storage member 13 in which the pressure-sensitive adhesive layer, the PET substrate (A), the easy adhesion layer, the heat storage layer 1, and a protective layer M having a thickness of 6 μm are stacked in this order was manufactured according to the method described in Example 12 except that the protective layer M having a thickness of 6 μm was formed by using the composition G for forming the protective layer.

### Example 14

A composition H for forming the protective layer was prepared by dissolving 0.4 part by mass of acetic acid, 15.0 parts by mass of X-12-1098 (manufactured by Shin-Etsu Chemical Co., Ltd.), 15.0 parts by mass of KBE-04 (manufactured by Shin-Etsu Chemical Co., Ltd.; silane coupling agent) and 1.5 parts by mass of Noigen LP-70 (manufactured by DKS Co., Ltd. (used by being diluted in 2% by mass of concentration of solid contents); surfactant) in 68.1 parts by mass of pure water, and stirring the mixed solution for 2 hours.

A heat storage member 14 in which the pressure-sensitive adhesive layer, the PET substrate (A), the easy adhesion layer, the heat storage layer 1, and a protective layer N having a thickness of 3 μm are stacked in this order was manufactured according to the method described in Example 1 except that the composition H for forming the protective layer obtained as above was used instead of the composition A for forming the protective layer and the coating film of the composition H for forming the protective layer was dried at 100° C. for 3 minutes.

### Example 15

A heat storage member 15 in which the pressure-sensitive adhesive layer, the PET substrate (A), the easy adhesion layer, the heat storage layer 1, and a protective layer O having a thickness of 6 μm are stacked in this order was manufactured according to the method described in Example 14 except that the protective layer O having a thickness of 6 μm was formed by using the composition H for forming the protective layer.

### Example 16

A liquid J was prepared by dissolving 0.4 part by mass of acetic acid, 24.0 parts by mass of X-12-1098 (manufactured by Shin-Etsu Chemical Co., Ltd.), 6.0 parts by mass of KBE-04 (manufactured by Shin-Etsu Chemical Co., Ltd.; silane coupling agent) and 1.5 parts by mass of Noigen LP-70 (manufactured by DKS Co., Ltd. (used by being diluted in 2% by mass of concentration of solid contents); surfactant) in 68.1 parts by mass of pure water, and stirring the mixed solution for 2 hours. 8 parts by mass of pure water, 67 parts by mass of liquid J, and 25 parts by mass of Snowtex OYL (manufactured by Nissan Chemical Corporation, silica particle) were mixed to produce a coating liquid, and the obtained coating liquid was defined as a composition K for forming the protective layer.

A heat storage member 16 in which the pressure-sensitive adhesive layer, the PET substrate (A), the easy adhesion layer, the heat storage layer 1, and a protective layer P having a thickness of 3 μm are stacked in this order was manufactured according to the method described in Example 1 except that the composition K for forming the protective layer obtained as above was used instead of the composition A for forming the protective layer and the coating film of the composition K for forming the protective layer was dried at 100° C. for 3 minutes.

### Example 17

A heat storage member 17 in which the pressure-sensitive adhesive layer, the PET substrate (A), the easy adhesion layer, the heat storage layer 1, and a protective layer Q having a thickness of 6 μm are stacked in this order was manufactured according to the method described in Example 16 except that the protective layer Q having a thickness of 6 μm was formed by using the composition K for forming the protective layer.

### Example 18

A PET substrate (B) with an easy adhesion layer and a pressure-sensitive adhesive layer was manufactured according to the method described in Example 1 except that the PET substrate having a thickness of 6 μm was used instead of the PET substrate having a thickness of 12 μm.

A composition L for forming the protective layer was prepared by mixing 24.2 parts by mass of KYNAR Aquatec ARC (manufactured by Arkema, 44% by mass of concentration of solid contents; fluorine-containing resin), 21.4 parts by mass of Epocros WS-700 (manufactured by Nippon Shokubai Co., Ltd., 25% of concentration of solid contents; curing agent), 33.2 parts by mass of FUJI JET BLACK B-15 (manufactured by Fuji Pigment Co., Ltd., 15% by mass of concentration of solid contents; carbon black), 20.0 parts by mass of Taien E (manufactured by Taihei Chemical Industrial Co., Ltd.; flame retardant), and 1.2 parts by mass of Noigen LP-70 (manufactured by DKS Co., Ltd. (diluted in an aqueous solution which has 2% by mass of concentration of solid contents); surfactant).

The composition 1 for forming the heat storage layer prepared in Example 1 was applied on the surface of the easy adhesion layer side of the PET substrate (B) with the easy adhesion layer and the pressure-sensitive adhesive layer by a bar coater such that the mass after drying was 172 g/m², the coating film was dried at 80° C. for 25 minutes, and was allowed to stand in the constant-temperature and constant-humidity tank at 50% RH and 25° C. for 2 hours to form a heat storage layer 2 having a thickness of 190 μm.

The composition L for forming the protective layer was applied on the surface of the heat storage layer 2 on the side opposite to the surface in contact with the easy adhesion layer, and the coating film was dried at 60° C. for 2 minutes to form a protective layer R having a thickness of 3 μm.

As a result, a heat storage member 18 in which the pressure-sensitive adhesive layer, the PET substrate (B), the easy adhesion layer, the heat storage layer 2, and the protective layer R are stacked in this order was manufactured.

### Example 19

A composition M for forming the protective layer was prepared by mixing 4.3 parts by mass of pure water, 0.4 parts by mass of 1M sodium hydroxide aqueous solution, 47.2 parts by mass of X-12-1098 (manufactured by Shin-Etsu Chemical Co., Ltd., 30% by mass of concentration of solid contents), 15.2 parts by mass of Snowtex XL (manufactured by Nissan Chemical Corporation, 40% by mass of concentration of solid contents, silica particle, 60 nm of average particle diameter), 31.7 parts by mass of FUJI JET BLACK B-15 (manufactured by Fuji Pigment Co., Ltd., 15% by mass of concentration of solid contents, carbon black), and 1.2 parts by mass of Noigen LP-70 (manufactured by DKS Co., Ltd. (diluted in an aqueous solution with 2% by mass of the concentration of solid contents); surfactant).

A heat storage member 19 in which the pressure-sensitive adhesive layer, the PET substrate (B), the easy adhesion layer, the heat storage layer 1, and a protective layer S having a thickness of 3 μm are stacked in this order was manufactured according to the method described in Example 18 except that the composition M for forming the protective layer described above was used instead of the composition A for forming the protective layer.

### Example 20

A composition N for forming the protective layer was prepared by mixing 11.4 parts by mass of KYNAR Aquatec ARC (manufactured by Arkema, 44% by mass of concentration of solid contents; fluorine-containing resin), 10.1 parts by mass of Epocros WS-700 (manufactured by Nippon Shokubai Co., Ltd., 25% by mass of concentration of solid contents; curing agent), 15.63 parts by mass of FUJI JET BLACK B-15 (manufactured by Fuji Pigment Co., Ltd., 15% by mass of concentration of solid contents, carbon black), 15.6 parts by mass of Taien E (manufactured by Taihei Chemical Industrial Co., Ltd.; flame retardant), 11.7 parts by mass of Noigen LP-70 (manufactured by DKS Co., Ltd. (diluted in an aqueous solution with 2% by mass of the concentration of solid contents); surfactant), and 11.7 parts by mass of 1,2-bis(3,3,4,4,5,5,6,6,6-nonafluorohexyloxycarbonyl) sodium ethanesulfonate (W-AHE, manufactured by FUJIFILM Corporation) (diluted in an aqueous solution with 0.5% by mass of the concentration of solid contents; surfactant).

A heat storage member 20 in which the pressure-sensitive adhesive layer, the PET substrate (B), the easy adhesion layer, the heat storage layer 1, and a protective layer T having a thickness of 3 μm are stacked in this order was manufactured according to the method described in Example 18 except that the composition N for forming the protective layer was used instead of the composition A for forming the protective layer.

### Example 21

A composition O for forming the protective layer was prepared by mixing 16.3 parts by mass of KYNAR Aquatec ARC (manufactured by Arkema, 44% by mass of concentration of solid contents; fluorine-containing resin), 14.4 parts by mass of Epocros WS-700 (manufactured by Nippon Shokubai Co., Ltd., 25% of concentration of solid contents; curing agent), 22.4 parts by mass of FUJI JET BLACK B-15 (manufactured by Fuji Pigment Co., Ltd., 15% by mass of concentration of solid contents; carbon black), 13.5 parts by mass of Taien E (manufactured by Taihei Chemical Industrial Co., Ltd.; flame retardant), and 16.7 parts by mass of Noigen LP-70 (manufactured by DKS Co., Ltd. (diluted in an aqueous solution which has 2% by mass of concentration of solid contents); surfactant).

The composition 1 for forming the heat storage layer prepared in Example 1 was applied on the surface of the easy adhesion layer side of the PET substrate (B) with the easy adhesion layer and the pressure-sensitive adhesive layer by a bar coater such that the mass after drying was 143 g/m², dried at 100° C. for 10 minutes, the composition 1 for forming the heat storage layer was applied such that the mass after drying was 29 g/m², then the composition O for forming the protective layer described above was applied, and the coating film was dried at 45° C. for 2 minutes to form a heat storage layer 3 having a thickness of 190 μm and a protective layer U having a thickness of 3 μm.

As a result, a heat storage member 21 in which the pressure-sensitive adhesive layer, the PET substrate (B), the easy adhesion layer, the heat storage layer 3, and the protective layer U are stacked in this order was manufactured.

### Example 22

A composition P for forming the protective layer was prepared by dissolving and dispersing 31.6 parts by mass of pure water, 29.6 parts by mass of Taien E (manufactured by Taihei Chemical Industrial Co., Ltd.; flame retardant), and 3.0 parts by mass of Noigen LP-70 (manufactured by DKS Co., Ltd. (diluted in an aqueous solution which has 2% by mass of concentration of solid contents); surfactant) in 35.8 parts by mass of KYNAR Aquatec ARC (manufactured by Arkema, 44% by mass of concentration of solid contents; fluorine-containing resin).

A heat storage member 22 in which the pressure-sensitive adhesive layer, the PET substrate (A), the easy adhesion layer, the heat storage layer 1, and a protective layer V having a thickness of 8 μm are stacked in this order was manufactured according to the method described in Example 2 except that the composition P for forming the protective layer obtained as above was used instead of the composition B for forming the protective layer.

### Comparative Example 1

A composition X for forming the protective layer was prepared by dissolving 16 parts by mass of polyvinyl alcohol (Kuraray Poval (registered trademark) KL-318 (manufactured by Kuraray Co., Ltd.; PVA) in 84 parts by mass of pure water.

A heat storage member C1 in which the pressure-sensitive adhesive layer, the PET substrate (A), the easy adhesion layer, the heat storage layer 1, and a protective layer X having a thickness of 8 μm are stacked in this order was manufactured according to the method described in Example 2 except that the composition X for forming the protective layer obtained as above was used instead of the composition B for forming the protective layer.

### Evaluation

The following evaluations were carried out for each of the heat storage members manufactured in Examples 1 to 22 and Comparative Example 1. The results of evaluation are shown in Tables 1 to 3, which will be described below.

### (Evaluation of Crosslinking Structure)

A sample having a size of 2 cm square was cut out from each heat storage member, and the sample was immersed in 50 ml of water. The sample was extracted after being stirred with a stirrer for 10 minutes. The water solubility of the protective layer was evaluated based on the criteria as follows by visually confirming whether or not the protective layer remains on the surface of the extracted sample.

3: The protective layer remains.

2: A small amount of the protective layer remains.

1: The protective layer does not remain.

The test was carried out according to the above method except that 50 ml of N,N-dimethylformamide was used instead of water, and the solvent solubility of the protective layer was evaluated based on the criteria as follows.

3: The protective layer remains

2: A small amount of the protective layer remains.

1: The protective layer does not remain.

In a case in which the above evaluations of water solubility and solvent solubility were both “3”, it was evaluated that the protective layer of each heat storage member has a structure that is insoluble in either water or solvent, that is, a crosslinking structure.

(Evaluation of Flame Retardance)

A sample having a size of 12.5 cm in length and 1.3 cm in width was cut out from each heat storage member, and the sample and an aluminum plate having a thickness of 0.3 mm were attached such that the pressure-sensitive adhesive layer of the sample was in contact with the aluminum plate to produce three samples with the aluminum plates. According to the method of UL94HB standard (Underwriters Laboratories Inc.), the heat storage member side of each sample with the aluminum plate was in contact with flame, and the presence or absence of ignition was confirmed. From the number of ignited samples among the three samples with the aluminum plates, the flame retardance of the heat storage member was evaluated based on the criteria as follows.

4: None of three samples with aluminum plates ignited.

3: One sample with aluminum plate ignited.

2: Two samples with aluminum plates ignited.

1: Three samples with aluminum plates ignited.

### Evaluation of Fissuring

The surface of the protective layer disposed on the outermost layer of each heat storage member manufactured in each Example and Comparative Example 1 was observed at a magnification of 200 times by using SEM. From the state of fissuring on the surface of the protective layer, the fissuring on the surface of the protective layer was evaluated based on the criteria as follows.

3: No fissuring is present on the surface of the protective layer.

2: A small amount of fissuring is present on the surface of the protective layer.

1: A large amount of fissuring is present on the surface of the protective layer.

### Measurement of Latent Heat Capacity

The latent heat capacity of the heat storage member which was obtained was calculated from the result of the differential scanning calorimetry (DSC) and the thickness of the heat storage layer.

### Measurement of Elongation Ratio at time of Tensile Breaking

The elongation ratio of the obtained heat storage member at the time of tensile breaking was measured according to the above method. The elongation ratios of the heat storage members obtained in Examples 1 to 22 were all in a range of 30% to 100%.

(Measurement of Tensile Strength)

The tensile strengths of the heat storage members manufactured in Example 2, Examples 5 to 18, Example 20, and Example 21 were measured according to the above method. The tensile strength of each heat storage member was in a range of 10 to 20 MPa.

TABLE 1

| | | | Example 1 | Example 2 | Example 3 | Example 4 | Example 5 |
|---|---|---|---|---|---|---|---|
| Heat storage | Pressure-sensitive adhesive | | Presence | Presence | Presence | Presence | Presence |
| member | layer | | | | | | |
| configuration | Substrate | | PET substrate | PET substrate | PET substrate | PET substrate | PET substrate |
| | | | (A) | (A) | (A) | (A) | (A) |
| | Easy adhesion layer | | Presence | Presence | Presence | Presence | Presence |
| | Heat storage layer | | 1 | 1 | 1 | 1 | 1 |
| | Protective | Composition for | A | B | C | D | B |
| | layer | forming protective | | | | | |
| | | layer | | | | | |
| | | Type | Curing film | Curing film | Hydrolysis | Hydrolysis | Curing film |
| | | | (KR516) | (KYNAR | condensate | condensate | (KYNAR ARC, |
| | | | | ARC, WS-700, | film | film | WS-700, |
| | | | | TAIEN E) | (X-12-1098) | (X-12-1098) | TAIEN E) |
| | | Thickness (μm) | 8 | 8 | 1 | 3 | 2 |
| | | Crosslink property | 3 | 3 | 3 | 3 | 3 |
| | | evaluation (water) | | | | | |
| | | Crosslink property | 3 | 3 | 3 | 3 | 3 |
| | | evaluation (DMF) | | | | | |

| Heat storage | Flame retardance | 2 | 4 | 3 | 3 | 4 |
|---|---|---|---|---|---|---|
| member | Fissuring | 1 | 3 | 2 | 2 | 3 |
| evaluation | Latent heat capacity (J/ml) | 130 | 132 | 135 | 133 | 134 |
| | Latent heat capacity (J/g) | 154 | 156 | 164 | 161 | 163 |
| | | | Example 6 | Example 7 | Example 8 | Example 9 |
| Heat storage | Pressure-sensitive adhesive | | Presence | Presence | Presence | Presence |
| member | layer | | | | | |
| configuration | Substrate | | PET substrate | PET substrate | PET substrate | PET substrate |
| | | | (A) | (A) | (A) | (A) |
| | Easy adhesion layer | | Presence | Presence | Presence | Presence |
| | Heat storage layer | | 1 | 1 | 1 | 1 |
| | Protective | Composition for | B | B | E | E |
| | layer | forming protective | | | | |
| | | layer | | | | |
| | | Type | Curing film | | Hydrolysis condensate | |
| | | | (KYNAR ARC, | | film | |
| | | | WS-700, | | (X-12-1098 / KBE-04 = 9/1) | |
| | | | TAIEN E) | | | |
| | | Thickness (μm) | 5 | 15 | 3 | 6 |
| | | Crosslink property | 3 | 3 | 3 | 3 |
| | | evaluation (water) | | | | |
| | | Crosslink property | 3 | 3 | 3 | 3 |
| | | evaluation (DMF) | | | | |

| | | | | | |
|---|---|---|---|---|---|
| Heat storage | Flame retardance | 4 | 4 | 2 | 3 |
| member | Fissuring | 3 | 3 | 3 | 3 |
| evaluation | Latent heat capacity (J/ml) | 132 | 124 | 134 | 131 |
| | Latent heat capacity (J/g) | 159 | 145 | 162 | 157 |

TABLE 2

| | | | Example 10 | Example 11 | Example 12 | Example 13 |
|---|---|---|---|---|---|---|
| Heat storage | Pressure-sensitive adhesive | | Presence | Presence | Presence | Presence |
| member | layer | | | | | |
| configuration | Substrate | | PET substrate | PET substrate | PET substrate | PET substrate |
| | | | (A) | (A) | (A) | (A) |
| | Easy adhesion layer | | Presence | Presence | Presence | Presence |
| | Heat storage layer | | 1 | 1 | 1 | 1 |
| | Protective | Composition for | F | F | G | G |
| | layer | forming protective | | | | |
| | | layer | | | | |
| | | Type | Hydrolysis condensate film | | Hydrolysis condensate film | |
| | | | (X-12-1098 / KBE-04 = 8/2) | | (X-12-1098 / KBE-04 = 7/3) | |
| | | Thickness (μm) | 3 | 6 | 3 | 6 |
| | | Crosslink property | 3 | 3 | 3 | 3 |
| | | evaluation (water) | | | | |
| | | Crosslink property | 3 | 3 | 3 | 3 |
| | | evaluation (DMF) | | | | |
| Heat storage | Flame retardance | | 2 | 3 | 2 | 3 |
| member | Fissuring | | 3 | 3 | 3 | 3 |
| evaluation | Latent heat capacity (J/ml) | | 134 | 132 | 134 | 131 |
| | Latent heat capacity (J/g) | | 162 | 158 | 162 | 157 |
| | | | | Example 15 | Example 16 | Example 17 |
| Heat storage | Pressure-sensitive adhesive | | Presence | Presence | Presence | Presence |
| member | layer | | | | | |
| configuration | Substrate | | PET substrate | PET substrate | PET substrate | PET substrate |
| | | | (A) | (A) | (A) | (A) |
| | Easy adhesion layer | | Presence | Presence | Presence | Presence |
| | Heat storage layer | | 1 | 1 | 1 | 1 |
| | Protective | Composition for | H | H | K | K |
| | layer | forming protective | | | | |
| | | layer | | | | |
| | | Type | Hydrolysis condensate film | | Hydrolysis condensate film | |
| | | | (X-12-1098 / KBE-04 = 5/5) | | (X-12-1098 / KBE-04 = 8/2, silica | |
| | | | | | particle) | |
| | | Thickness (μm) | 3 | 6 | 3 | 6 |
| | | Crosslink property | 3 | 3 | 3 | 3 |
| | | evaluation (water) | | | | |
| | | Crosslink property | 3 | 3 | 3 | 3 |
| | | evaluation (DMF) | | | | |

| | | | | | |
|---|---|---|---|---|---|
| Heat storage | Flame retardance | 2 | 3 | 2 | 3 |
| member | Fissuring | 3 | 3 | 3 | 3 |
| evaluation | Latent heat capacity (J/ml) | 133 | 130 | 135 | 133 |
| | Latent heat capacity (J/g) | 161 | 156 | 161 | 157 |

TABLE 3

| | | | Example 18 | Example 19 | Example 20 |
|---|---|---|---|---|---|
| Heat storage | Pressure-sensitive adhesive layer | | Presence | Presence | Presence |
| member | Substrate | | PET substrate (B) | PET substrate (B) | PET substrate (B) |
| configuration | Easy adhesion layer | | Presence | Presence | Presence |
| | Heat storage layer | | 2 | 2 | 2 |
| | Protective | Composition for forming | L | M | N |
| | layer | protective layer | | | |
| | | Type | Curing film | Hydrolysis | Curing film |
| | | | (KYNAR ARC, | condensate film | (KYNAR ARC, |
| | | | WS-700, B-15, | (X-12-1098, B-15, | WS-700, B-15, |
| | | | TAIEN E) | silica particle) | TAIEN E) |
| | | Thickness (μm) | 3 | 3 | 3 |
| | | Crosslink property | 3 | 3 | 3 |
| | | evaluation (water) | | | |
| | | Crosslink property | 3 | 3 | 3 |
| | | evaluation (DMF) | | | |
| Heat storage | Flame retardance | | 4 | 2 | 4 |
| member | Fissuring | | 3 | 2 | 3 |
| evaluation | Latent heat capacity (J/ml) | | 190 | 190 | 191 |
| | Latent heat capacity (J/g) | | 161 | 160 | 167 |
| | | | | | Comparative |
| | | | Example 21 | Example 22 | Example 1 |
| Heat storage | Pressure-sensitive adhesive layer | | Presence | Presence | Presence |
| member | Substrate | | PET substrate (B) | PET substrate (A) | PET substrate (A) |
| configuration | Easy adhesion layer | | Presence | Presence | Presence |
| | Heat storage layer | | 3 | 1 | 1 |
| | Protective | Composition for forming | O | P | X |
| | layer | protective layer | | | |
| | | Type | Curing film | Curing film | Gel film (PVA) |
| | | | (KYNAR ARC, | (KYNAR ARC, | |
| | | | WS-700, B-15, | TAIEN E) | |
| | | | TAIEN E) | | |
| | | Thickness (μm) | 3 | 8 | 8 |
| | | Crosslink property | 3 | 3 | 1 |
| | | evaluation (water) | | | |
| | | Crosslink property | 3 | 3 | 1 |
| | | evaluation (DMF) | | | |

| | | | | |
|---|---|---|---|---|
| Heat storage | Flame retardance | 4 | 2 | 1 |
| member | Fissuring | 3 | 1 | 3 |
| evaluation | Latent heat capacity (J/ml) | 191 | 132 | 132 |
| | Latent heat capacity (J/g) | 170 | 156 | 156 |

From the results shown in Tables 1 to 3, it was confirmed that the heat storage member according to the present disclosure is excellent in flame retardance.

The heat storage member according to the present disclosure can suitably be used, for example, as heat storage and heat radiation members for stable operation by maintaining the surface temperature of a heat generating unit in the electronic device in any temperature range. Also, it can be suitably used in applications such as building materials (for example, flooring materials, roofing materials, wall materials, and the like) which are suitable for temperature control to rapid temperature rise during the day or during indoor heating and cooling; clothing (for example, underwear, outerwear, winter clothes, gloves, and the like) which is suitable for temperature control depending on the changes in environmental temperature or changes in body temperature during exercise or rest; bedding; and an exhaust heat utilization system which stores unnecessary exhaust heat and uses it as thermal energy.

What is claimed is:

1. A heat storage member comprising:
a protective layer; and
a heat storage layer including a heat storage material,
wherein the protective layer has a crosslinking structure.

2. The heat storage member according to claim 1,
wherein the protective layer includes at least one selected from the group consisting of a resin containing a fluorine atom and a siloxane condensate.

3. The heat storage member according to claim 1,
wherein the protective layer includes a flame retardant containing a phosphorus atom.

4. The heat storage member according to claim 1,
wherein the protective layer includes a curing agent.

5. The heat storage member according to claim 1,
wherein no fissuring is present on a surface of the protective layer opposite to a surface thereof facing the heat storage layer.

6. The heat storage member according to claim 1,
wherein the protective layer has a thickness of 10 μm or less.

7. The heat storage member according to claim 1,
wherein a ratio of a thickness of the protective layer to a thickness of the heat storage layer is 1/20 or less.

8. The heat storage member according to claim 1,
wherein an elongation ratio at the time of tensile breaking is 20% or more.

9. The heat storage member according to claim 1,
wherein the heat storage layer and the protective layer are in contact with each other.

10. The heat storage member according to claim 1,
wherein a content ratio of the heat storage material to a total mass of the heat storage layer is 65% by mass or more.

11. The heat storage member according to claim 1,
wherein the heat storage layer includes a microcapsule which encompasses at least a part of the heat storage material.

12. The heat storage member according to claim 1,
wherein the heat storage material includes a latent heat storage material.

13. The heat storage member according to claim 1,
wherein a content of the heat storage material having a largest content included in the heat storage layer to contents of all of the heat storage materials included in the heat storage layer is 98% by mass or more.

14. An electronic device comprising the heat storage member according to claim 1.

15. The electronic device according to claim 14, further comprising a heat generating body.

16. A manufacturing method of a heat storage member which includes a heat storage layer including a heat storage material and a protective layer having a crosslinking structure, the method comprising:
disposing the protective layer to be in contact with at least one surface of the heat storage layer.

17. A composition for forming a protective layer comprising:
at least one selected from the group consisting of a resin containing a fluorine atom and a siloxane resin or a precursor thereof; and
a flame retardant containing a phosphorus atom.

18. The heat storage member according to claim 2,
wherein the protective layer includes a flame retardant containing a phosphorus atom.

19. The heat storage member according to claim 2,
wherein the protective layer includes a curing agent.

20. The heat storage member according to claim 2,
wherein no fissuring is present on a surface of the protective layer opposite to a surface thereof facing the heat storage layer.
